(19) United States
(12) Patent Application Publication
(10) Pub. No.: US 2016/0133702 A1
(43) Pub. Date: May 12, 2016

(54) SEMICONDUCTOR DEVICE AND METHOD OF MANUFACTURING THE SAME

(71) Applicants: JAE-HYUN YOO, SUWON-SI (KR); KWAN-YOUNG KIM, SEOUL (KR); JIN-HYUN NOH, SEOUL (KR); WOO-YEOL MAENG, GUNPO-SI (KR); KEE-MOON CHUN, SEONGNAM-SI (KR); YONG-WOO JEON, SEOUL (KR)

(72) Inventors: JAE-HYUN YOO, SUWON-SI (KR); KWAN-YOUNG KIM, SEOUL (KR); JIN-HYUN NOH, SEOUL (KR); WOO-YEOL MAENG, GUNPO-SI (KR); KEE-MOON CHUN, SEONGNAM-SI (KR); YONG-WOO JEON, SEOUL (KR)

(21) Appl. No.: 14/733,354

(22) Filed: Jun. 8, 2015

(30) Foreign Application Priority Data
Nov. 6, 2014 (KR) 10-2014-0153739

(51) Int. Cl. H01L 29/10; H01L 29/06; H01L 29/36; H01L 27/088; H01L 29/78

(52) U.S. Cl. CPC H01L 29/1045; H01L 27/0886; H01L 29/7816; H01L 29/36; H01L 29/7851; H01L 29/7831; H01L 29/0649

(57) ABSTRACT

A semiconductor device includes a substrate having a first conductive type active region, a second conductive type drift region in the active region, a gate covering the active region on the drift region, a gate insulating film disposed between the active region and the gate, a second conductive type drain region in a location spaced apart from the gate in the drift region and having a higher doping concentration than that of the drift region, a first conductive type shallow well region spaced apart from the drain region in the drift region and between the gate and the drain region, and a second conductive type source region formed in the first conductive type shallow well region between the gate and the drain region and having a higher doping concentration than that of the first conductive type shallow well region.

### CROSS-REFERENCE TO RELATED APPLICATIONS

A claim of priority under 35 U.S.C. §119 is made to Korean Patent Application No. 10-2014-0153739, filed on Nov. 6, 2014, in the Korean Intellectual Property Office, the disclosure of which is incorporated herein in its entirety by reference.

### BACKGROUND

The inventive concepts described herein relate to semiconductor devices and methods of manufacturing semiconductor devices, and more particularly, to semiconductor devices including a lateral diffused metal oxide semiconductor (LDMOS) transistor and methods of manufacturing such semiconductor devices.

Responsive to the recent increase in use of mobile devices such as cellular phones, notebooks, PCs, etc., the demand for power semiconductor devices is rapidly increasing. Power semiconductor devices may be divided into power switching devices and control integrated circuits (ICs). An ideal power switching device used in a power semiconductor device should have a high breakdown voltage that is endurable when switched off, a large allowable current, a small on-resistance, a small amount of switch driving power, and short switching time when switched on. To implement an ideal power switching device for use in a power semiconductor device, it is necessary to secure an extended safe operating area (SOA).

### SUMMARY

The inventive concept herein relates to a semiconductor device capable of securing an extended safe operating area (SOA), providing excellent electrical performance, and having a structure capable of being employed in a highly scaled high integrated semiconductor device.

The inventive concept also relates to a method of manufacturing a semiconductor device capable of securing an SOA, providing excellent electrical performance, and being employed in a highly scaled high integrated semiconductor device by using a simplified process.

Embodiments of the inventive concept provide a semiconductor device including a substrate having an active region of a first conductive type; a drift region of a second conductive type in the active region; a gate covering the active region and in the drift region; a gate insulating film disposed between the active region and the gate; a drain region of the second conductive type in the drift region, spaced apart from the gate, and having a higher doping concentration than the drift region; a shallow well region of the first conductive type between the gate and the drain region and spaced apart from the drain region, and in the drift region; and a source region of the second conductive type in the shallow well region between the gate region and the drain region and having a higher doping concentration than the shallow well region.

In some embodiments, the semiconductor device may further include an insulating spacer covering side surfaces of the gate. The source region is adjacent to the insulating spacer and spaced apart from the gate, and the gate insulating film and the insulating spacer are between the source region and the gate.

In some embodiments, the semiconductor device may further include a body contact region of the first conductive type in the shallow well region of the first conductive type between the source region and the drain region, and spaced apart from the drain region.

In some embodiments, the substrate may include a main surface; and a fin type semiconductor region protruding from the main surface and extending in a first direction parallel to the main surface of the substrate. The active region is defined in the fin type semiconductor region.

In some embodiments, the gate may extend in a second direction crossing the active region on the substrate.

In some embodiments, the gate may include a first vertical gate unit and a second vertical gate unit facing two side surfaces of the active region. The gate insulating film is between the first vertical gate unit and one of the two side surfaces of the active region, and between the second vertical gate unit and an other of the two side surfaces of the active region.

In some embodiments, the gate may include a first vertical gate unit, a second vertical gate unit, and a horizontal gate unit integrally connected to the first vertical gate unit and the second vertical gate unit. The first vertical gate unit and the second vertical gate unit face two side surfaces of the active region, with the gate insulating film therebetween. The horizontal gate unit faces an upper surface of the active region, and the gate insulating film is between the horizontal gate unit and the upper surface of the active region.

In some embodiments, the substrate may be a bulk substrate, and the gate is a planar type gate on the bulk substrate.

Embodiments of the inventive concept provide a semiconductor device including a substrate having an active region of a first conductive type; a drift region of a second conductive type in the active region; a gate region including at least one gate covering the active region and on the drift region; at least one gate insulating film disposed between the active region and the at least one gate; a first shallow well region and a second shallow well region of the first conductive type in the drift region and spaced apart from each other, the gate region is between the first shallow well region and the second shallow well region. The semiconductor device further includes a first source region of the second conductive type in the first shallow well region and having a higher doping concentration than the first shallow well region; a second source region of the second conductive type in the second shallow well region and having a higher doping concentration than the first shallow well region; and a first drain region and a second drain region of the second conductive type in the drift region and spaced apart from each other and the gate region. The first shallow well region and the second shallow well region are between the first drain region and the second drain region, and the first drain region and the second drain region have a higher doping concentration than the drift region.

In some embodiments, the gate region may include a common gate and the semiconductor device may include a first lateral diffused metal oxide semiconductor (LDMOS) transistor including the first source region and the first drain region in the drift region, and a second LDMOS transistor including the second source region and the second drain region in the drift region. The common gate is shared by the first LDMOS transistor and the second LDMOS transistor.

In some embodiments, the semiconductor device may further include a first insulating spacer and a second insulating spacer covering side surfaces of the common gate. The first source region is formed adjacent to the first insulating spacer and the second source region is formed adjacent to the second insulating spacer.

In some embodiments, the semiconductor device may further include a first body contact region of the first conductive type in the first shallow well region, between the first source region and the first drain region, and spaced apart from the first drain region; and a second body contact region of the first conductive type in the second shallow well region, between the second source region and the second drain region, and spaced apart from the second drain region.

In some embodiments, the gate region may include a first gate and a second gate spaced apart from each other, and the semiconductor device may include a first LDMOS transistor including the first gate region, the first source region, and the first drain region in the drift region; and a second LDMOS transistor including the second gate region, the second source region, and the second drain region in the drift region.

In some embodiments, the semiconductor device may further include a first insulating spacer covering side surfaces of the first gate and a second insulating spacer covering side surfaces of the second gate. The first source region is adjacent to the first insulating spacer and the second source region is adjacent to the second insulating spacer.

In some embodiments, the semiconductor device may further include a first body contact region of the first conductive type in the first shallow well region, between the first source region and the first drain region, and spaced apart from the first drain region; and a second body contact region of the first conductive type in the second shallow well region, between the second source region and the second drain region, and spaced apart from the second drain region.

In some embodiments, the semiconductor device may further include a device isolation film in the drift region, between the first gate and the second gate.

In some embodiments, the semiconductor device may further include a first body contact region of the first conductive type in the first shallow well region, between the first source region and the first drain region, and spaced apart from the first drain region; a second body contact region of the first conductive type in the second shallow well region, between the second source region and the second drain region, and spaced apart from the second drain region; and a third body contact region in the drift region, between the first gate and the second gate.

In some embodiments, the semiconductor device may further include a first body contact region of the first conductive type in the first shallow well region, between the first source region and the first drain region, and spaced apart from the first drain region; a second body contact region of the first conductive type in the second shallow well region, between the second source region and the second drain region, and spaced apart from the second drain region; and an impurity region of the first conductive type in the drift region between the first gate and the second gate. The impurity region is electrically floating.

In some embodiments, the substrate may include a main surface and a fin type semiconductor region protruding from the main surface of the substrate and extending in a first direction parallel to the main surface of the substrate. The active region is defined in the fin type semiconductor region.

In some embodiments, the at least one gate may extend in a second direction crossing the active region on the substrate.

In some embodiments, the at least one gate may be line shaped and covers two side surfaces of the fin type semiconductor region. The at least one gate insulating film may be between the at least one gate and both side surfaces of the fin type semiconductor region.

In some embodiments, the substrate may be a bulk substrate, and the at least one gate may be a planar type gate on the bulk substrate.

Embodiments of the inventive concept provide a semiconductor device including a fin type active region of a first conductive type on a substrate and extending in a first direction; a gate region on the substrate, extending in a direction crossing the fin type active region, and including at least one gate covering two side surfaces of the fin type active region; a first source region and a second source region of a second conductive type in the fin type active region at two side surfaces of the gate region; a first drain region of the second conductive type in the fin type active region and spaced apart from the gate region, wherein the first source region is between the first drain region and the gate region; a second drain region of the second conductive type in the fin type active region and spaced apart from the gate region, wherein the second source region is between the second drain region and the gate region; and a drift region of the second conductive type in the fin type active region and surrounding the gate region, the first source region, the second source region, the first drain region, and the second drain region.

In some embodiments, the semiconductor device may further include a first well of the first conductive type in the drift region and surrounding the first source region; and a second well of the first conductive type in the drift region and surrounding the second source region.

In some embodiments, the semiconductor device may further include a first body contact region of the first conductive type adjacent to the first source region and in the first well, wherein the first body contact region has a higher doping concentration than the first well; and a second body contact region of the first conductive type adjacent to the second source region and in the second well, wherein the second body contact region has a higher doping concentration than the second well.

In some embodiments, the gate region may include a common gate, and the semiconductor device may include a first LDMOS transistor including the first source region and the first drain region in the drift region; and a second LDMOS transistor including the second source region and the second drain region in the drift region. The common gate may be shared by the first LDMOS transistor and the second LDMOS transistor.

In some embodiments, the gate region may include a first gate and a second gate spaced apart from each other, and the semiconductor device may include a first LDMOS transistor including the first gate region, the first source region, and the first drain region in the drift region; and a second LDMOS transistor including the second gate region, the second source region, and the second drain region in the drift region.

In some embodiments, the semiconductor device may further include a first conductive type body contact region between the first gate and the second gate.

In some embodiments, the semiconductor device may further include a device isolation film between the first gate and the second gate.

Embodiments of the inventive concept provide a semiconductor device including a fin type active region of a first conductive type on a substrate and extending in a first direction; a gate on the substrate, extending in a direction crossing the fin type active region, and covering two side surfaces of the fin type active region; a drift region in the fin type active region; a drain region of a second conductive type in the drift region and spaced apart from the gate by a first distance; a shallow well region of the first conductive type in the fin type active region; and a source region of the second conductive type in the shallow well region and spaced apart from the gate by a second distance smaller than the first distance.

Embodiments of the inventive concept provide a semiconductor device including a substrate including an active region of a first conductive type; a drift region of a second conductive type in the active region; and two LDMOS transistors sharing the drift region and disposed symmetrically within the drift region.

In some embodiments, the two LDMOS transistors may include one common gate shared by the two LDMOS transistors. The two LDMOS transistors are disposed symmetrically with respect to the common gate.

In some embodiments, the two LDMOS transistors may include a first LDMOS transistor including a first gate and a second LDMOS transistor including a second gate spaced apart from the first gate. The two LDMOS transistors are disposed symmetrically with respect to the first gate and the second gate.

Embodiments of the inventive concept provide a method of manufacturing a semiconductor device, the method including forming a drift region of a second conductive type in an active region of a substrate, wherein the active region is of a first conductive type; forming a shallow well region of a first conductive type in the drift region; sequentially forming a gate insulating film and a gate, the gate including a corner portion overlapping with the shallow well region in the active region; forming a drain region of a second conductive type in the drift region, adjacent to and spaced apart from the gate and the shallow well region; and forming a source region in the shallow well region, between the gate and the drain region.

In some embodiments, the method may further include forming a body contact region of a first conductive type in the shallow well region, between the source region and the drain region.

In some embodiments, the active region may be configured as a fin type active region including two side walls and an upper surface. The forming of the gate includes forming the gate to cover the two side walls and the upper surface of the fin type active region.

Embodiments of the inventive concept provide a method of manufacturing a semiconductor device, the method including forming a second conductive type drift region in a first conductive type active region of a substrate; and forming two LDMOS transistors in the drift region.

In some embodiments, the forming of the two LDMOS transistors may include forming a common gate shared by the two LDMOS transistors. The two LDMOS transistors are disposed symmetrically with respect to the common gate.

In some embodiments, the forming of the two LDMOS transistors may include forming two gates shared by the two LDMOS transistors. The two LDMOS transistors are disposed symmetrically with respect to the two gates.

Embodiments of the inventive concept provide a method of manufacturing a semiconductor device, the method including forming a second conductive type drift region in a first conductive type active region of a substrate; forming a first shallow well region and a second shallow well region both of a first conductive type in the drift region; forming at least one gate in the active region between the first shallow well region and the second shallow well region; forming a first drain region and a second drain region in the drift region, wherein the first shallow well region and the second shallow well region are between the first drain region and the second drain region; and forming a first source region in the first shallow well region and a second source region in the second shallow well region.

In some embodiments, the forming of the first drain region and the second drain region may include forming the first drain region in a location spaced apart from the first shallow well region, wherein the first shallow well region is between the first drain region and the at least one gate; and forming the second drain region in a location spaced apart from the second shallow well region, wherein the second shallow well region is between the second drain region and the at least one gate.

In some embodiments, the forming of the at least one gate may include forming one common gate including a first corner portion overlapping with the first shallow well region and a second corner portion overlapping with the second shallow well region.

In some embodiments, the forming of the at least one gate may include forming a first gate including a corner portion overlapping with the first shallow well region; and forming a second gate including a corner portion overlapping with the second shallow well region and spaced apart from the first gate.

In some embodiments, the forming of the first gate and the forming of the second gate are simultaneously performed.

### BRIEF DESCRIPTION OF THE DRAWINGS

Exemplary embodiments of the inventive concept will be more clearly understood from the following detailed description taken in conjunction with the accompanying drawings in which:

FIGS. 1A, 1B and 1C are diagrams illustrating a semiconductor device, according to an embodiment of the inventive concept.

FIGS. 2A and 2B are diagrams illustrating a semiconductor device, according to another embodiment of the inventive concept.

FIGS. 3A and 3B are diagrams illustrating a semiconductor device, according to another embodiment of the inventive concept.

FIG. 4 is a cross-sectional view illustrating a semiconductor device, according to another embodiment of the inventive concept.

FIGS. 5A through 5C are diagrams illustrating a semiconductor device, according to another embodiment of the inventive concept.

FIG. 6 is a cross-sectional view illustrating a semiconductor device, according to another embodiment of the inventive concept.

FIGS. 7A, 7B and 7C are diagrams illustrating a semiconductor device, according to another embodiment of the inventive concept.

FIG. 8 is a cross-sectional view illustrating a semiconductor device, according to another embodiment of the inventive concept.

FIGS. 9A, 9B and 9C are diagrams illustrating a semiconductor device, according to another embodiment of the inventive concept.

FIGS. 10A, 10B and 10C are diagrams illustrating a semiconductor device, according to another embodiment of the inventive concept.

FIG. 11 is a cross-sectional view illustrating a semiconductor device, according to another embodiment of the inventive concept.

FIG. 12 is a plan view illustrating a semiconductor device, according to another embodiment of the inventive concept.

FIG. 13 is a plan view illustrating a semiconductor device, according to another embodiment of the inventive concept.

FIG. 14 is a plan view illustrating a semiconductor device, according to another embodiment of the inventive concept.

FIG. 15 is a plan view illustrating a semiconductor device, according to another embodiment of the inventive concept.

FIG. 16A is an equivalent circuit diagram illustrating a CMOS inverter including a semiconductor device, according to another embodiment of the inventive concept.

FIG. 16B is an example illustrating a layout of an inverter for implementing the CMOS inverter of FIG. 16A including an equivalent circuit.

FIG. 16C is another example illustrating a layout of an inverter for implementing the CMOS inverter of FIG. 16A including an equivalent circuit.

FIGS. 17A, 17B, 17C, 17D, 17E, 17F, 17G, 17H, 17I and 17J are cross-sectional views illustrating sequentially a method of manufacturing a semiconductor device, according to embodiments of the inventive concept.

FIGS. 18A, 18B, 18C, 18D, 18E and 18F are cross-sectional views illustrating sequentially a method of manufacturing a semiconductor device, according to embodiments of the inventive concept.

FIGS. 19A and 19B are cross-sectional views illustrating sequentially a method of manufacturing a semiconductor device, according to embodiments of the inventive concept.

FIG. 20 is a graph illustrating a relationship between a drain current and a drain voltage of semiconductor devices according to embodiments of the inventive concept and of semiconductor devices according to comparative examples.

FIG. 21 is a graph illustrating a relationship between a substrate current and a drain voltage of semiconductor devices according to another embodiment of the inventive concept and of semiconductor devices according to a comparative example.

FIG. 22 is a block diagram illustrating a semiconductor system including a semiconductor device, according to an embodiment of the inventive concept.

FIG. 23 is a block diagram illustrating a semiconductor system including a semiconductor device, according to another embodiment of the inventive concept.

FIG. 24 is a diagram illustrating a tablet PC including a semiconductor device, according to an embodiment of the inventive concept.

FIG. 25 is a diagram illustrating a notebook including a semiconductor device, according to an embodiment of the inventive concept.

### DETAILED DESCRIPTION OF THE EMBODIMENTS

Hereinafter, the inventive concept will be described in detail by explaining exemplary embodiments of the inventive concept with reference to the attached drawings. Like reference numerals in the drawings denote like elements, and thus their description will be omitted.

The inventive concept may, however, be embodied in many different forms and should not be construed as limited to the exemplary embodiments set forth herein. Rather, these embodiments are provided so that this disclosure will be thorough and complete, and will fully convey the scope of the inventive concept to those skilled in the art. In the drawings, lengths and sizes of layers and regions may be exaggerated for clarity.

Also, though terms like ‘first’ and ‘second’ are used to describe various elements, components, regions, layers, and/or portions in various embodiments of the inventive concept, the elements, components, regions, layers, and/or portions should not be limited by these terms. These terms are only used to distinguish one element, component, region, layer, or portion from another. Thus, a first element, component, region, layer or portion discussed below could be termed a second element, component, region, layer or portion without departing from the teachings of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment can be embodied in a different manner, a specified process order may be performed in a different manner in order to be described. For example, two processes to be described sequentially may be substantially performed at the same time or may be performed in an order opposite to the order to be described.

As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. As used herein, the term “and/or” includes any and all combinations of one or more of the associated listed items. Expressions such as “at least one of,” when preceding a list of elements, modify the entire list of elements and do not modify the individual elements of the list.

In the present specification, the term MOS (metal-oxide-semiconductor) is a term widely used in the field of semiconductors. “M” is not limited to only metal, and “M” may refer to conductors of various types and various shapes. “S” may refer to a substrate or a semiconductor structure. “O” is not limited to an oxide, and “O” may refer to various types of inorganic materials or organic materials. The term “semiconductor” may include a monocrystal, a polycrstyal, an amorphous semiconductor, a Group IV semiconductor, or a compound semiconductor. Conductive types of elements or doping regions may be defined as “P type” or “N type” according to a characteristic of a main carrier, but this is merely for convenience of description and the inventive concept is not limited to the descriptions above. For example, “P type” or “N type” may be used as a more general term “first conductive type” or “second conductive type”. In this regard, the first conductive type may be P type or N type, and the second conductive type may be N type or P type. In reference numerals, an element denoted by a reference numeral with a prime ′ may correspond to an element denoted by a reference numeral without the prime ′, except that the element denoted by the reference numeral with a prime ′ has conductive type opposite to that of the element denoted by the reference numeral without the prime ′.

Hereinafter, N-channel lateral diffused metal oxide semiconductor (LDMOS) devices are described as an example of semiconductor devices according to the inventive concept. However, the example is only for convenience of description and the inventive concept is not limited to the descriptions above. Various semiconductor devices and circuits including a combination of not only P-channel LDMOS devices but also a combination of P-channel LDMOS and N-channel LDMOS devices may be provided through various modifications and changes within the scope of the inventive concept.

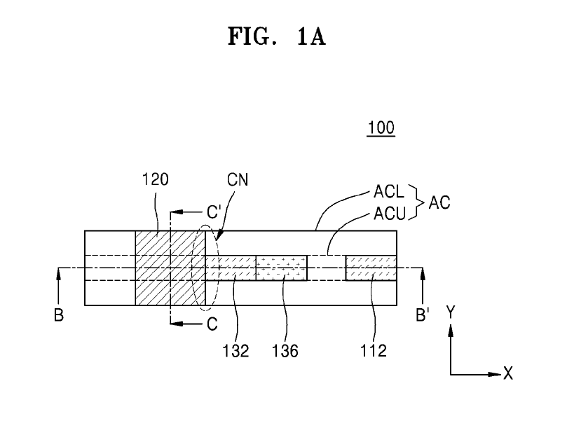

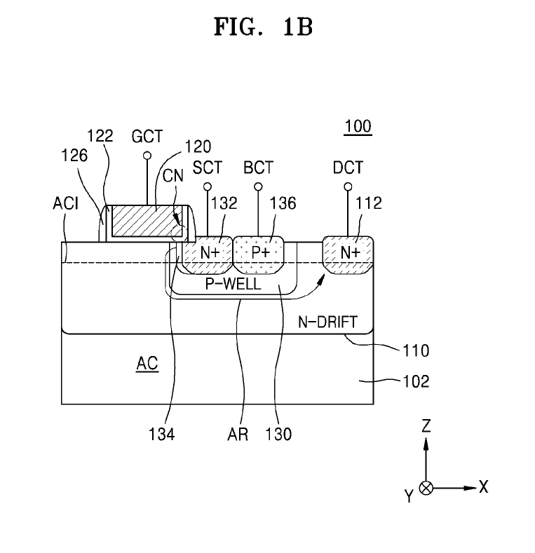

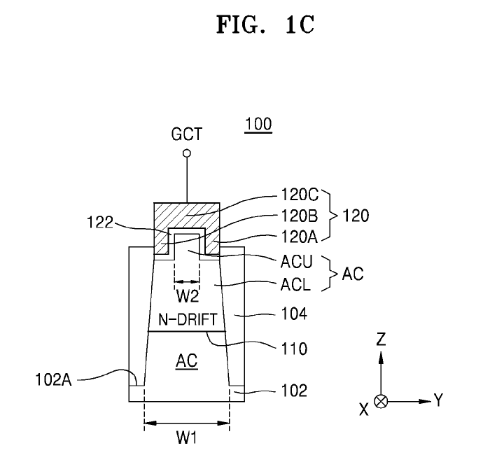

FIGS. 1A, 1B and 1C are diagrams illustrating a semiconductor device 100, according to an embodiment of the inventive concept. The semiconductor device 100 formed as a fin type LDMOS transistor including a fin body will now be described with reference to FIGS. 1A through 1C. FIG. 1A is a plan view of main elements of the semiconductor device 100. FIG. 1B is a cross-sectional view of a line B-B′ of FIG. 1A. FIG. 1C is a cross-sectional view of a line C-C′ of FIG. 1A.

Referring to FIGS. 1A through 1C, the semiconductor device 100 includes a substrate 102 having a first conductive type active region AC, a second conductive type drift region 110 formed in the active region AC, and a gate 120 covering the active region AC on the drift region 110. A gate insulating layer 122 is disposed between the active region AC and the gate 120.

FIGS. 1A through 1C illustrate an example where the semiconductor device 100 constitutes an N-channel LDMOS. Accordingly, in the example, the first conductive type is a P type, and the second conductive type is an N type.

The substrate 102 may include a semiconductor such as Si or Ge or a compound semiconductor such as SiGe, SiC, GaAs, InAs, or InP. In other example embodiments, the substrate 102 may have a silicon-on-insulator (SOI) structure.

The active region AC may be defined in a fin type semiconductor region limited in a line shape extending in a direction (X direction) parallel to a main surface 102A of the substrate 102 by a device isolation layer 104. The active region AC includes a lower fin active region ACL having a first width W1 and an upper fin active region ACU integrally connected to the lower fin active region ACL and having a second width W2 smaller than the first width W1. Each of the lower fin active region ACL and the upper fin active region ACU may have the line shape extending in the direction (X direction) parallel to the main surface 102A of the substrate 102.

The device isolation layer 104 has an upper surface of a higher level than that of an upper surface of the lower fin active region ACL. The upper fin active region ACU protrudes upward in a Z direction from the lower fin active region ACL to a level higher than that of the upper surface of the device isolation layer 104. In FIG. 1B, a level of a boundary part between the lower fin active region ACL and the upper fin active region ACU is indicated in a broken line ACI.

The device isolation layer 104 may be formed as an oxide layer, a nitride layer, or a combination of these but is not limited thereto.

The gate 120 has a line shape extending in a direction (Y direction) crossing the active region AC on the substrate 102. The gate 120 includes a first vertical gate unit 120A and a second vertical gate unit 120B facing both sides of the upper fin active region ACU with the gate insulating layer 122 therebetween, and a horizontal gate unit 120C facing an upper surface of the upper fin active region ACU with the gate insulating layer 122 therebetween. Accordingly, a triple gate structure in which channels are formed in both sides and the upper surface of the upper fin active region ACU is implemented. In other embodiments, differently then as shown in FIGS. 1A through 1C, a double gate structure in which no channel is formed in the upper surface of the upper fin active region ACU and channels are formed in both sides of the upper fin active region ACU may be implemented, the double gate structure having first and second vertical gate units without a horizontal gate unit.

A gate contact terminal GCT is connected to the gate 120. A metal silicide layer, for example a nickel silicide layer, may be disposed between the gate 120 and the gate contact terminal GCT. An ohmic contact may be formed between the gate 120 and the gate contact terminal GCT.

The gate 120 may be formed of conductive polysilicon, metal, conductive metal nitride, or a combination of these. Each of the metal and the conductive metal nitride may include at least one selected from the group consisting of Ti, Ta, W, Ru, Nb, MO, and Hf, while not limited thereto. The metal nitride may be formed of TiN, TaN, or a combination of these, while not limited thereto. The gate 120 may be formed through chemical vapor deposition (CVD), physical vapor deposition (PVD), atomic layer deposition (ALD), metal organic ALD (MOALD), or metal organic CVD (MOCVD)

The gate insulating layer 122 may be formed of silicon oxide film, a high dielectric film, or a combination of these. The high dielectric film may be formed of a material having a higher dielectric constant than that of silicon oxide film. For example, the gate insulating layer 122 may have a dielectric constant from about 10 and to about 25. The high dielectric film may be formed of a material selected from the group consisting of hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, while not limited thereto. The gate insulating layer 122 may be formed through ALD, CVD, or PVD.

Both sides of each of the gate 120 and the gate insulating layer 122 may be covered by an insulating spacer 126. The insulating spacer 126 may be formed as an oxide film, a nitride film, or a combination of these.

To implement the semiconductor device 100 formed of the N-channel LDMOS, the drift region 110 is formed as an N type doping region. A drain region 112 is formed in a position spaced apart from the gate 120 in the drift region 110. The drain region 112 is formed as an N+ type doping region having a higher doping concentration than that of the drift region 110. Side surfaces and the bottom surface of the drain region 112 are surrounded by the drift region 110.

The drain contact terminal DCT is connected to the drain region 112. In some embodiments, a metal silicide film, for example a nickel silicide film, may be disposed between the drain region 112 and the drain contact terminal DCT. An ohmic contact may be formed between the drain region 112 and the drain contact terminal DCT.

A first conductive type shallow well region 130 is formed spaced apart from the drain region 112 in the drift region 110. The shallow well region 130 is formed to overlap with a corner portion CN indicated in a broken line in FIGS. 1A and 1B, i.e. the corner portion CN of a side of the gate 120 facing the drain region 112. The shallow well region 130 is formed as a P type doping region. The shallow well region 130 is formed as having a smaller depth than that of the drift region 110 in the active region AC. Accordingly, side surfaces and the bottom surface of the shallow well region 130 are surrounded by the drift region 110.

A source region 132 is formed in the shallow well region 130 between the gate 120 and the drain region 112. The source region 132 is formed as an N+ type doping region having a higher doping concentration than that of the shallow well region 130. Side surfaces and the bottom surface of the source region 132 are surrounded by the shallow well region 130. In other embodiments the source region 132 may be formed at a position spaced apart from the gate 120 with the gate insulating layer 122 and the insulating spacer 126 therebetween.

An extension region 134 formed as an N type doping region having a lower doping concentration than that of the source region 132 is formed in a lower portion of the gate 120 in one side of the source region 132 in the active region AC. A source region of a lightly doped drain (LDD) structure is formed by the source region 132 and the extension region 134. The extension region 134 may be formed in a position arranged by the gate 120. The source region 132 may be formed in a position arranged by the insulating spacer 126.

A source contact terminal SCT is formed in the source region 132. In some embodiments, a metal silicide layer, for example a nickel silicide layer, may be disposed between the source region 132 and the source contact terminal SCT. An ohmic contact may be formed between the source region 132 and the source contact terminal SCT.

A body contact region 136 is formed in a position adjacent to the source region 132 in the shallow well region 130. The body contact region 136 is formed between the source region 132 and the drain region 112 in the shallow well region 130. The body contact region 136 has a higher doping concentration than that of the shallow well region 130. The body contact region 136 is formed as a P+ type doping region.

A body contact terminal BCT is connected to the body contact region 136. In some embodiments, a metal silicide layer, for example a nickel silicide layer, may be disposed between the body contact region 136 and the body contact terminal BCT. An ohmic contact may be formed between the body contact region 136 and the body contact terminal BCT.

The source region 132 and the body contact region 136 are adjacent to each other in FIGS. 1A and 1B but the inventive concept is not limited thereto. For example, in other embodiments the source region 132 and the body contact region 136 may be spaced apart from each other in the shallow well region 130.

FIGS. 1A and 1B illustrate the semiconductor device 100 formed as a 4 terminal LDMOS device including the gate contact terminal GCT, the drain contact terminal DCT, the source contact terminal SCT, and the body contact terminal BCT.

In the semiconductor device 100 described with reference to FIGS. 1A through 1C, the source region 132 and the body contact region 136 are formed in the drift region 110.

When the semiconductor device 100 is in a stand-by state, a high voltage may be applied to the drain region 112 while the gate 120, the body contact region 132, and the source region 132 are grounded. To operate the semiconductor device 100, a voltage may be applied to the gate 120 when in the stand-by state. When a voltage higher than a limit voltage of the semiconductor device 100 is applied to the gate 120, electrons move to the drain region 112 from the source region 132 through a channel path inside the upper fin active region ACU. As indicated by the arrow AR shown in FIG. 1B, current flows to the drain region 112 from the source region 132 through the channel path, and via a lower portion of the upper fin active region ACU and the drift region 110 in the lower fin active region ACL. In this regard, since the source region 132 and the body contact region 136 are formed in the drift region 110, a specific on-resistance Rsp formed between the gate 120 and the drain region 112 in the drift region 110 is reduced compared to a case where the source region 132 and the body contact region 136 are not formed in the drift region 110. The shallow well region 130 is present between the corner portion CN of the gate 120 and the drift region 110 so that the gate 120 and the drift region 110 do not directly contact each other. Thus, as indicated by the arrow AR shown in FIG. 1B, a current does not flow through the corner portion CN of the gate 120. Accordingly, an electric field concentration that might occur at the corner portion CN of the gate 120 is prevented. Thus, a phenomenon in which a breakdown voltage is degraded due to the electric field concentration in the drift region 110 is prevented, a substrate current Isub is reduced, and a drain induced barrier lowering (DIBL) phenomenon that results in a leakage current generated in the drain region 112 by a drain voltage, and deterioration of electrical characteristics such as a short channel effect (SCE), a parasitic capacitance (bonding capacitance), etc., are prevented. Accordingly, safe operating area (SOA) limits of a source-drain current and a source-drain voltage by which the semiconductor device may safely operate without electrical deterioration or a malfunction may be increased, and electrical performance may be improved.

The source region 132 and the body contact region 136 are formed in the drift region 110, and thus not only is the specific on-resistance Rsp reduced, but an area occupied by one LDMOS transistor may be dramatically reduced compared to a case where the source region 132 and the body contact region 136 are formed outside the drift region 110. That is, as a comparative example, when the source region 132 and the body contact region 136 are formed outside the drift region 110 at an opposite side of the drift region 110 with respect to the gate 120, the specific on-resistance Rsp may be undesirably increased between the gate 120 and the drain region 112 in the drift region 110. However, the source region 132 and the body contact region 136 occupy a part of the drift region 110 that may cause the specific on-resistance Rsp, and thus the semiconductor device 100 according to the inventive concept where the source region 132 and the body contact region 136 are formed in the drift region 110 may reduce the specific on-resistance Rsp between the gate 120 and the drain region 112 in the drift region 110. When compared to the structure of the comparative example in which the source region 132 and the body contact region 136 are formed outside the drift region 110 and occupy a separate area, the separate area outside the drift region 110 is unnecessary, and thus an area occupied by one LDMOS transistor may be dramatically reduced. Thus, the semiconductor device 100 may be preferably employed in a highly scaled high integrated semiconductor device.

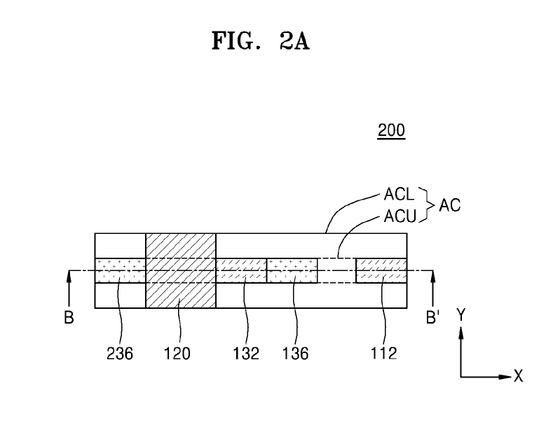

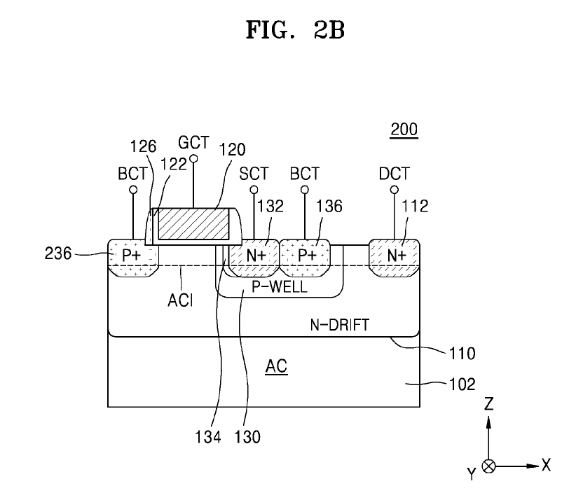

FIGS. 2A and 2B are diagrams illustrating a semiconductor device 200, according to another embodiment of the inventive concept. The semiconductor device 200 configured as an LDMOS transistor including a plurality of body contact regions will be described with reference to FIGS. 2A and 2B. FIG. 2A is a plan view of main elements of the semiconductor device 200. FIG. 2B is a cross-sectional view of a line B-B′ in FIG. 2A. The same reference numerals denote the same elements in FIGS. 2A and 2B and FIGS. 1A through 1C, and thus detailed descriptions thereof are omitted.

The semiconductor device 200 generally includes the same elements as those of the semiconductor device 100 of FIGS. 1A through 1C. However, the semiconductor device 200 further includes a body contact region 236 formed in the drift region 110 at an opposite side of the source region 132 with respect to the gate 120.

The body contact terminal BCT is connected to the body contact region 236. However, according to other embodiments, the body contact terminal BCT connected to the body contact region 236 may be omitted. In some embodiments, the body contact region 236 may include an electrically floating well region.

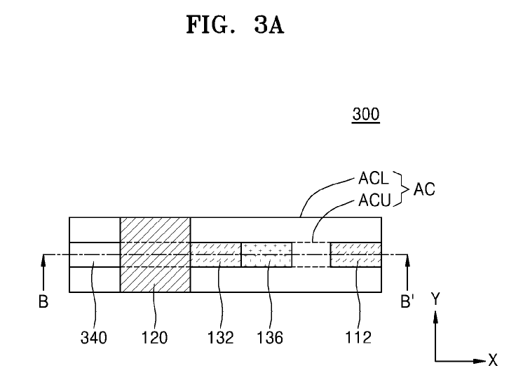

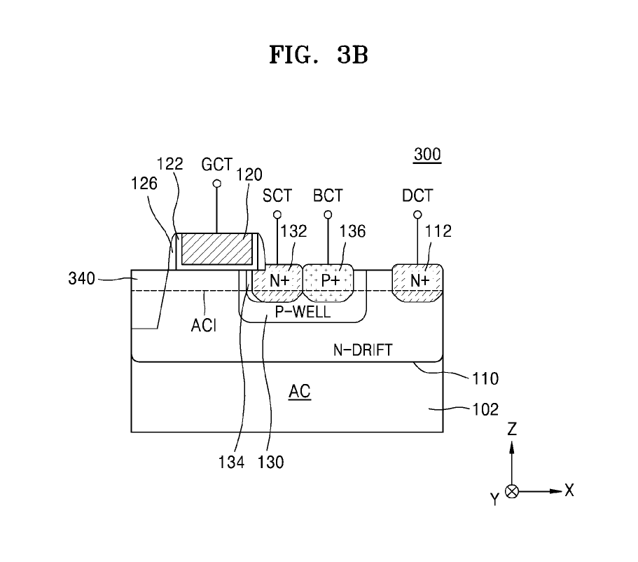

FIGS. 3A and 3B are diagrams illustrating a semiconductor device 300, according to another embodiment of the inventive concept. The semiconductor device 300 configured as an LDMOS transistor including a device isolation film partitioning a transistor region will be described with reference to FIGS. 3A and 3B. FIG. 3A is a plan view of main elements of the semiconductor device 300. FIG. 3B is a cross-sectional view of a line B-B′ of FIG. 3A. The same reference numerals denote the same elements in FIGS. 3A and 3B and FIGS. 1A through 1C, and thus detailed descriptions thereof are omitted.

The semiconductor device 300 generally includes the same elements as those of the semiconductor device 100 of FIGS. 1A through 1C. However, the semiconductor device 300 further includes a device isolation film 340 formed in the drift region 110 at an opposite side of the source region 132 with respect to the gate 120. The device isolation film 340 may be formed by performing a shallow trench isolation (STI) process, but is not limited thereto.

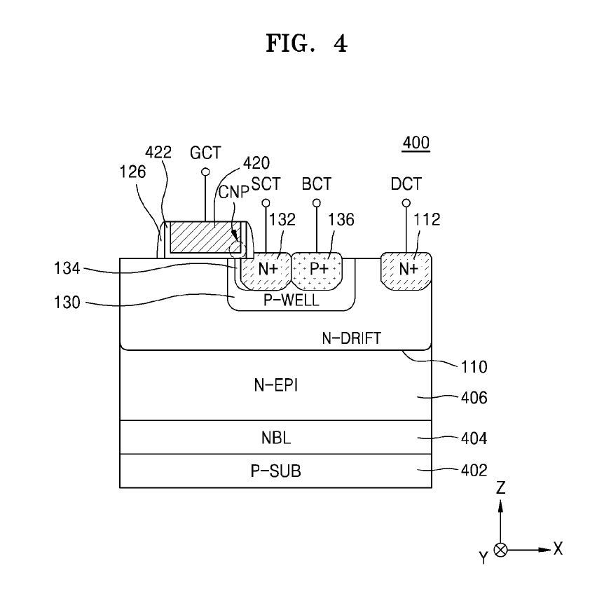

FIG. 4 is a cross-sectional view illustrating a semiconductor device, according to another embodiment of the inventive concept. FIG. 4 illustrates a semiconductor device 400 including a planar type LDMOS transistor implemented on a bulk substrate 402. The same reference numerals denote the same elements in FIG. 4 and FIGS. 1A through 1C, and thus detailed descriptions thereof are omitted.

Referring to FIG. 4, the semiconductor device 400 is implemented on the bulk substrate 402. The bulk substrate 402 is a semiconductor substrate doped with a first conductive type, for example, P type, impurity. In some embodiments, the bulk substrate 402 may include a semiconductor such as Si or Ge or a compound semiconductor such as SiGe, SiC, GaAs, InAs, or InP. In other embodiments, the bulk substrate 402 may be a ceramic substrate, a quartz substrate, or a display glass substrate.

A buried layer 404 is formed on the substrate 402. The buried layer 404 is configured as a buried layer doped with a second conductive type, for example, N type, impurity.

An epitaxial layer 406 is formed on the buried layer 404. The epitaxial layer 406 is doped with the second conductive type, for example N type impurity. However, a doping concentration of the epitaxial layer 406 may be lower than that of the buried layer 404.

An LDMOS transistor including a planar type gate 420 and having a similar structure as that described with reference to FIGS. 1A through 1C is formed on the epitaxial layer 406. A gate insulating layer 422 covering an upper surface of the drift region 110 and the planar type gate 420 are formed on the drift region 110. The drift region 110 formed in the epitaxial layer 406 is formed to have a planar upper surface, and the planar type gate 420 is formed to face the planar upper surface of the drift region 110 with the gate insulating layer 422 therebetween.

The drain region 112 spaced apart from the planar type gate 420 is formed in the drift region 110.

The shallow well region 130 is formed between the gate 420 and the drain region 112 in the drift region 110. The shallow well region 130 is formed to overlap with one side corner portion CNP of the gate 420. The source region 132 configured as an N+ type doping region is formed in a position adjacent to the planar type gate 420 in the shallow well region 130. The body contact region 136 is formed in the shallow well region 130 between the source region 132 and the drain region 112.

FIG. 4 illustrates a structure in which a planar type LDMOS transistor having a similar structure to that of the semiconductor device 100 described with reference to FIGS. 1A through 1C is formed on the epitaxial layer 406, but the inventive concept is not limited thereto. For example, in other embodiments a planar type LDMOS transistor having a similar structure to those of the semiconductor devices 200 and 300 described with reference to FIGS. 2A through 3B, or one of structures that are modified and changed in various ways within the inventive concept therefrom, may be formed on the epitaxial layer 406.

In the semiconductor device 400 illustrated in FIG. 4, the source region 132 and the body contact region 136 are formed in the drift region 110. Accordingly, in a similar manner as described with reference to FIGS. 1A through 1C, the specific on-resistance Rsp formed between the gate 120 and the drain region 112 in the drift region 110 is reduced. Since the shallow well region 130 is present between a corner portion of the gate 120 and the drift region 110, the gate 120 and the drift region 110 do not directly contact each other, and thus current flow does not pass through the corner portion CNP of the gate 420. Accordingly, the substrate current Isub is reduced by preventing an electric field concentration that might occur at the corner portion CN of the gate 120, thereby expanding the SOA boundary and improving electrical performance. The source region 132 and the body contact region 136 are formed in the drift region 110, thereby reducing the specific on-resistance Rsp between the gate 420 and the drain region 112, and dramatically reducing an area occupied by one LDMOS transistor.

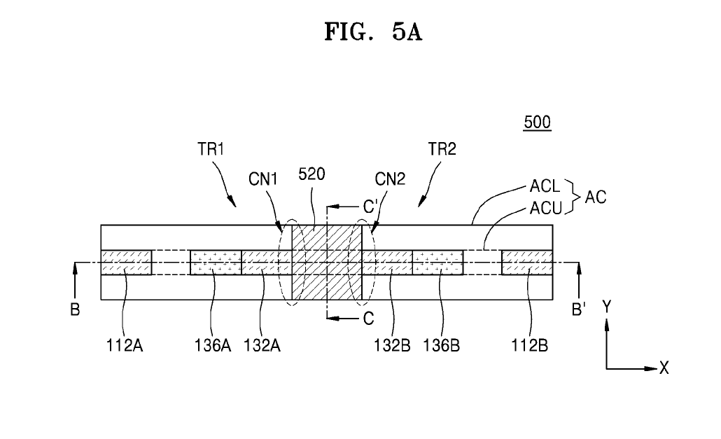

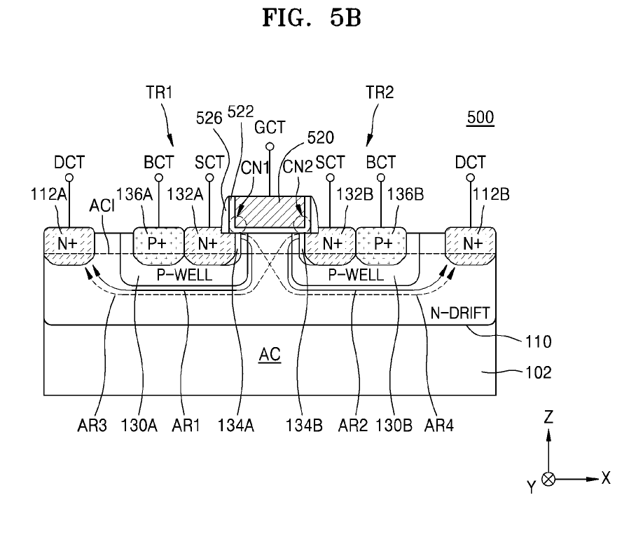

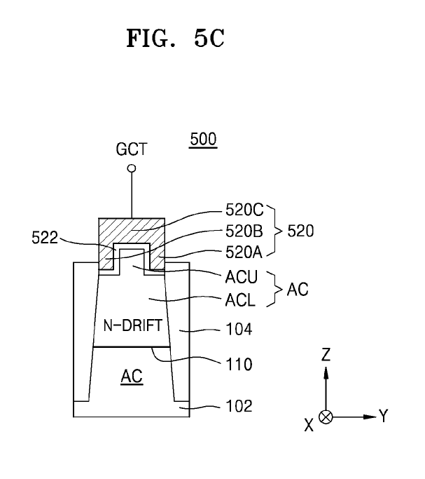

FIGS. 5A, 5B and 5C are diagrams illustrating a semiconductor device 500, according to another embodiment of the inventive concept. The semiconductor device 500 includes a plurality of fin type LDMOS transistors including a fin body and having a structure in which two adjacent fin type LDMOS transistors share one common gate. FIG. 5A is a plan view of main elements of the semiconductor device 500. FIG. 5B is a cross-sectional view of a line B-B′ of FIG. 5A. FIG. 5C is a cross-sectional view of a line C-C′ of FIG. 5A. The same reference numerals denote the same elements in FIGS. 5A through 5C and FIGS. 1A through 1C, and thus detailed descriptions thereof are omitted.

Referring to FIGS. 5A through 5C, the semiconductor device 500 includes the substrate 102 having the active region AC and the drift region 110 formed in the active region AC. A common gate 520 covering the active region AC is formed on the drift region 110. A gate insulating film 522 is disposed between the active region AC and the common gate 520.

FIGS. 5A through 5C illustrate a case where the semiconductor device 500 is configured as an N-channel LDMOS. Accordingly, in the present embodiment, a first conductive type is a P type, and a second conductive type is an N type.

The common gate 520 has have a line shape extending in a direction (Y direction) crossing the active region AC on the substrate 102. The common gate 520 includes a first vertical gate unit 520A and a second vertical gate unit 520B facing both sides of the upper fin active region ACU with the gate insulating film 522 therebetween, and a horizontal gate unit 520C integrally connected to the first vertical gate unit 520A and the second vertical gate unit 520B and facing an upper surface of the upper fin active region ACU with the gate insulation film 522 therebetween. Accordingly, a triple gate structure in which channels are formed in both sides and the upper surface of the upper fin active region ACU is implemented. Unlike the triple gate structure, in other embodiments a double gate structure in which a channel is not formed in the upper surface of the upper fin active region ACU and channels are formed in both sides of the upper fin active region ACU may be implemented, the double gate structure having first and second vertical gate units without a horizontal gate unit.

The gate contact terminal GCT is connected to the common gate 520. In some embodiments, a metal silicide layer, for example a nickel silicide layer, may be disposed between the common gate 520 and the gate contact terminal GCT. An ohmic contact may be formed between the common gate 520 and the gate contact terminal GCT. Both sides of the common gate 520 and the gate insulating film 522 may be covered with an insulating spacer 526.

For more details with respect to the common gate 520 and the gate insulating film 522, the descriptions of gate 120 and the gate insulating film 122 provided with reference to FIGS. 1A through 1C apply.

A P type first shallow well region 130A and a second shallow well region 130B that are spaced apart from each other with the common gate 520 therebetween are formed in the drift region 110. An N+ type first source region 132A is formed in the first shallow well region 130A. An N+ type second source region 132B is formed in the second shallow well region 130B.

A first drain region 112A and a second drain region 112B that are spaced apart from each other with the common gate 520, the first shallow well region 130A, and the second shallow well region 130B therebetween are formed in the drift region 110. The first drain region 112A and the second drain region 112B are configured as N+ type doping regions having a higher doping concentration than that of the drift region 110. The first drain region 112A and the second drain region 112B have side surfaces and bottom surfaces surrounded by the drift region 110.

The first source region 132A is formed between the common gate 520 and the first drain region 112A. Side surfaces and the bottom surface of the first source region 132A are surrounded by the first shallow well region 130A. The second source region 132B is formed between the common gate 520 and the second drain region 112B. Side surfaces and the bottom surface of the second source region 132B is surrounded by the second shallow well region 130B.

The first source region 132A and the second source region 132B are formed in a position spaced apart from the common gate 520 with the gate insulating film 522 and the insulating spacer 526 therebetween.

The source contact terminals SCT are formed in the first source region 132A and the second source region 132B. In some embodiments, a metal silicide layer, for example a nickel silicide layer, may be disposed between the first source region 132A and the second source region 132B and the source contact terminals SCT. An ohmic contact may be formed between the first source region 132A and the second source region 132B and the source contact terminals SCT.

The drain contact terminals DCT are connected to each of the first drain region 112A and the second drain region 112B. In some embodiments, a metal silicide layer, for example a nickel silicide layer, may be disposed between the first drain region 112A and the second drain region 112B and the drain contact terminals DCT. An ohmic contact may be formed between the first drain region 112A and the second drain region 112B and the drain contact terminals DCT.

The first shallow well region 130A and the second shallow well region 130B are respectively formed to partially overlap with both side corner portions CN1 and CN2 of the common gate 520, as indicated in broken line regions in FIGS. 5A and 5B.

The first shallow well region 130A and the second shallow well region 130B are configured as P type doping regions. The first shallow well region 130A and the second shallow well region 130B are formed as having smaller depth than that of the drift region 110 in the active region AC. Accordingly, each of the first shallow well region 130A and the second shallow well region 130B have side surfaces and bottom surfaces surrounded by the drift region 110.

A first extension region 134A and a second extension region 134B configured as N type doping regions having a lower doping concentration than that of the first source region 132A and the second source region 132B are disposed at lower parts of the common gate 520 in one side of each of the first source region 132A and the second source region 132B respectively, in the active region AC. A first source region having an LDD structure is thus formed by the first source region 132A and the first extension region 134A. A second source region having an LDD structure is thus formed by the second source region 132B and the second extension region 134B.

A first body contact region 136A is formed in a position adjacent to the first source region 132A in the first shallow well region 130A. A second body contact region 136B is formed in a position adjacent to the second source region 132B in the second shallow well region 130B. The first body contact region 136A is formed between the first source region 132A and the first drain region 112A in the first shallow well region 130A, and has a higher doping concentration than that of the first shallow well region 130A. The second body contact region 136B is formed between the second source region 132B and the second drain region 112B in the second shallow well region 130B, and has a higher doping concentration than that of the second shallow well region 130B. The first body contact region 136A and the second body contact region 136B are configured as P+ type doping regions.

The body contact terminals BCT are connected to each of the first body contact region 136A and the second body contact region 136B. In some embodiments, a metal silicide layer, for example a nickel silicide layer, may be disposed between the first body contact region 136A and the second body contact region 136B and the body contact terminals BCT. An ohmic contact may be formed between the first body contact region 136A and the second body contact region 136B and the body contact terminals BCT.

FIGS. 5A and 5B illustrate the first source region 132A and the first body contact region 136A that are adjacent to each other, and the second source region 132B and the second body contact region 136B that are adjacent to each other, but the inventive concept is not limited thereto. For example, in other embodiments the first source region 132A and the first body contact region 136A, and the second source region 132B and the second body contact region 136B, may be formed in positions spaced apart from each other.

In the semiconductor device 500 described with reference to FIGS. 5A through 5C, the first source region 132A and the first body contact region 136A, and the second source region 132B and the second body contact region 136B, are formed in the drift region 110. The semiconductor device 500 thus includes a first LDMOS transistor TR1 including the first source region 132A and the first drain region 112A, and a second LDMOS transistor TR2 including the second source region 132B and the second drain region 112B, and has a structure in which the common gate 520 and the drift region 110 are shared by the first LDMOS transistor TR1 and the second LDMOS transistor TR2. The first LDMOS transistor TR1 and the second LDMOS transistor TR2 have a reciprocally symmetrical shape with respect to the common gate 520.

In a stand-by status of the semiconductor device 500, a high voltage may be applied to the first drain region 112A and the second drain region 112B in a state in which the common gate 520, the first source region 132A, the first body contact region 136A, the second source region 132B, and the second body contact region 136B are grounded. To operate the semiconductor device 500, a voltage may be applied to the common gate 520 when in the stand-by status. When a voltage more than a limit voltage of the semiconductor device 500 is applied to the common gate 520, electrons move to the first drain region 112A and the second drain region 112B through each of channel paths inside the upper fin active region ACU from the first source region 132A and the second source region 132B. Current flows to the first drain region 112A and the second drain region 112B from the first source region 132A and the second source region 132B through the channel paths, and via lower portions of the upper fin active region ACU and the drift region 110 in the lower fin active region ACL. In this regard, since the first LDMOS transistor TR1 and the second LDMOS transistor TR2 have reciprocally symmetrical shape with respect to the common gate 520, in addition to a main current flow path starting from the first source region 132A and the second source region 132B as indicated in arrows AR1 and AR2, an auxiliary current flow path crossing to the first drain region 112A and to the second drain region 112B included in the first LDMOS transistor TR1 and the second LDMOS transistor TR2 is additionally formed as indicated by dotted line arrows AR3 and AR4. Accordingly, resistance is further reduced in the drift region 110.

As described above, since the first source region 132A and the first body contact region 136A, and the second source region 132B and the second body contact region 136B are formed in the drift region 110 in the semiconductor device 500, the specific on-resistance Rsp formed between the common gate 520 and the first drain region 112A, and between the common gate 520 and the second drain region 112B, is reduced in the drift region 110. The first shallow well region 130A and the second shallow well region 130B are present between the corner portion of the common gate 520 and the drift region 110 so that the common gate 520 and the drift region 110 do not directly contact each other. Thus, as indicated by the arrows AR1, AR2, AR3, and AR4 in FIG. 5B, the main current flow path and the auxiliary current flow path do not pass through the corner portions CN1 and CN2 of the common gate 520. Accordingly, an electric field concentration that might occur at the corner portions CN1 and CN2 of the common gate 520 is prevented. As described above, an electric field concentration phenomenon that occurs at the corner portions CN1 and CN2 of the common gate 520 is prevented, thereby preventing a phenomena in which a breakdown voltage is degraded due to the electric field concentration in the drift region 110, reducing the substrate current Isub, and preventing a DIBL phenomenon that generates a leakage current in the drain region 112 by a drain voltage, and an electrical characteristic deterioration such as a SCE, a parasitic capacitance, etc. Accordingly, an SOA boundary of the semiconductor device 500 is expanded, and electrical performance is improved.

In the semiconductor device 500, since the first source region 132A and the first body contact region 136A, and the second source region 132B and the second body contact region 136B, are formed in the drift region 110, the specific on-resistance Rsp formed between the common gate 520 and the first drain region 112A and between the common gate 520 and the second drain region 112B is reduced in the drift region 110, compared to a case where the first source region 132A and the first body contact region 136A, and the second source region 132B and the second body contact region 136B, are formed outside the drift region 110. Compared to a structure in which the first source region 132A and the first body contact region 136A, and the second source region 132B and the second body contact region 136B are formed outside the drift region 110 and occupy a separate area, an area occupied by one LDMOS transistor is dramatically reduced. Thus, the semiconductor device 500 may be preferably employed in a highly scaled high integrated semiconductor device.

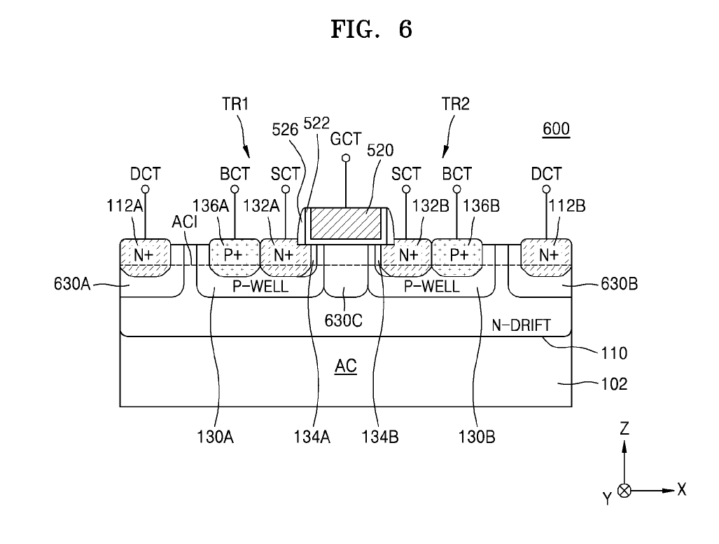

FIG. 6 is a cross-sectional view illustrating a semiconductor device 600, according to another embodiment of the inventive concept. Referring to FIG. 6, the semiconductor device 600 configured as an LDMOS transistor includes a third shallow well region 630A and a fourth shallow well region 630B respectively including the first drain region 112A and the second drain region 112B. The same reference numerals denote the same elements in FIG. 6 and FIGS. 1A through 5, and thus detailed descriptions thereof are omitted.

Referring to FIG. 6, the third shallow well region 630A surrounding the first drain region 112A and the fourth shallow well region 630B surrounding the second drain region 112B are formed in the drift region 110. The third shallow well region 630A and the fourth shallow well region 630B are configured as N type impurity doping regions. Resistances in the first drain region 112A and the second drain region 112B are reduced by the third shallow well region 630A and the fourth shallow well region 630B.

A fifth shallow well region 630C is formed in the active region AC under the common gate 520 in the drift region 110. The fifth shallow well region 630C is configured as an N type impurity doping region. The fifth shallow well region 630C is disposed between the first shallow well region 130A and the second shallow well region 130B. Resistance in a part of the drift region 110 providing a main current flow path and an auxiliary current flow path as indicated in the arrows AR1, AR2, AR3, and AR4 of FIG. 5B is reduced in FIG. 6 by forming the fifth shallow well region 630C. In some embodiments, the fifth shallow well region 630C may be omitted.

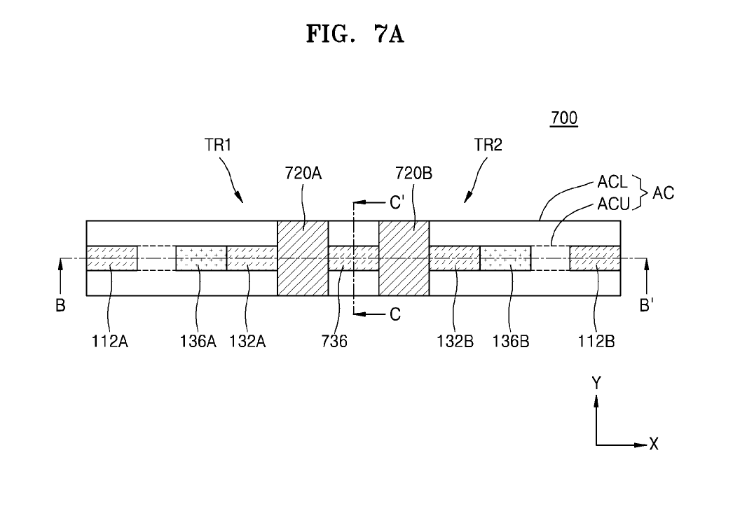

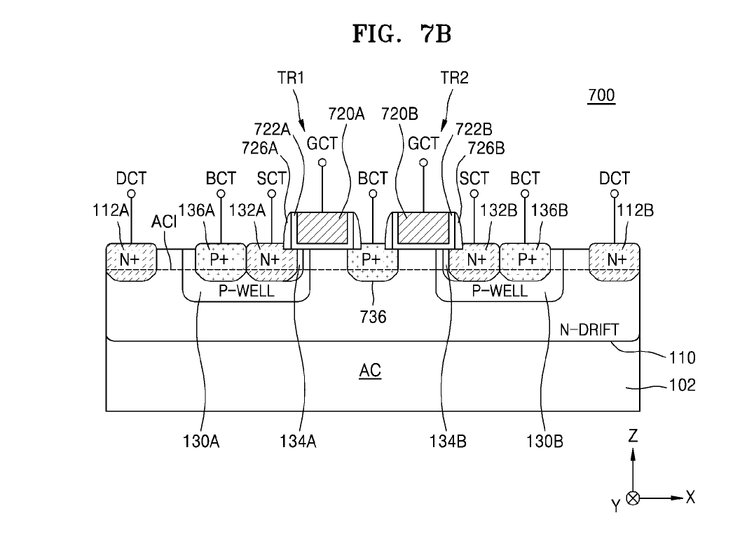

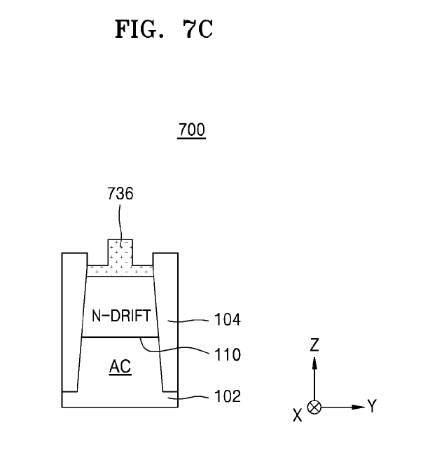

FIGS. 7A, 7B and 7C are diagrams illustrating a semiconductor device 700, according to another embodiment of the inventive concept. The semiconductor device 700 is configured as having LDMOS transistors including independent gates. FIG. 7A is a plan view of main elements of the semiconductor device 700. FIG. 7B is a cross-sectional view of a line B-B′ of FIG. 7A. FIG. 7C is a cross-sectional view of a line C-C′ of FIG. 7A. The same reference numerals denote the same elements in FIGS. 7A through 7C and FIGS. 1A through 5C, and thus detailed descriptions thereof are omitted.

The semiconductor device 700 generally includes the same configuration as that of the semiconductor device 500 described with reference to FIGS. 5A through 5C. However, the semiconductor device 700 includes a first gate 720A and a second gate 720B that are spaced apart from each other on the active region AC.

A first gate insulating film 722A is disposed between the active region AC and the first gate 720A. Both side walls of the first gate 720A and the first gate insulating film 722A are covered by a first insulating spacer 726A.

A second gate insulating film 722B is disposed between the active region AC and the second gate 720B. Both side walls of the second gate 720B and the second gate insulating film 722B are covered by a second insulating spacer 726B.

A third body contact region 736 is further provided in a region between the first gate 720A and the second gate 720B in the drift region 110. The body contact terminal BCT is connected to the third body contact region 736.

In the semiconductor device 700 illustrated in FIG. 7, similarly to the semiconductor device 500 illustrated in FIGS. 5A through 5C, electrons may move through each of channel paths formed in the upper fin active region ACU from the first source region 132A and the second source region 132B to the first drain region 112A and the second drain region 112B. That is, in the same manner as indicated in the arrows AR1 and AR2 of FIG. 5B, a main current flow path from the first source region 132A and the second source region 132B respectively to the first drain region 112A and the second drain region 112B in the lower fin active region ACL below the upper fin active region ACU via the drift region 110 is formed, and in the same manner as indicated in the arrows AR3 and AR4 of FIG. 5B, an auxiliary current flow path crossing to the first drain region 112A and to the second drain region 112B included in the first LDMOS transistor TR1 and the second LDMOS transistor TR2 respectively from the second source region 132B and the first source region 132A is formed. Accordingly, resistance is further reduced in the drift region 110.

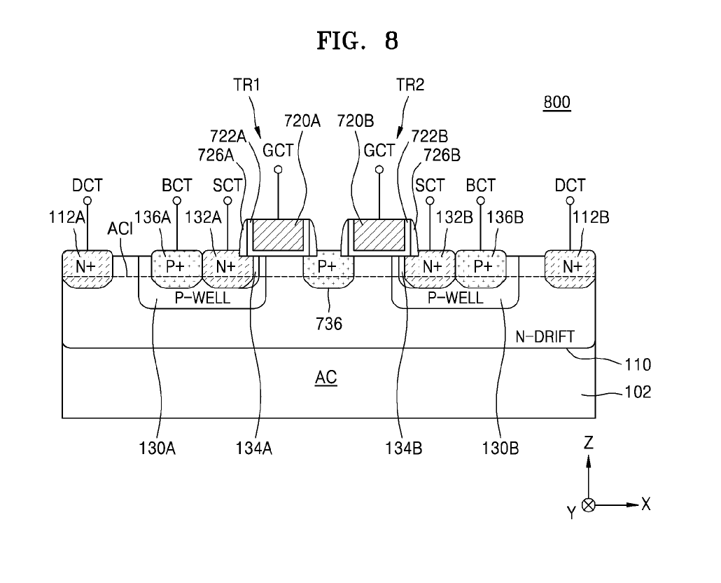

FIG. 8 is a cross-sectional view illustrating a semiconductor device 800, according to another embodiment of the inventive concept.

The semiconductor device 800 generally includes the same configuration as that of the semiconductor device 700 described with reference to FIGS. 7A through 7C. However, in the semiconductor device 800, the body contact terminal BCT is not connected to the third body contact region 736. The third body contact region 736 is configured as an electrically floating well region.

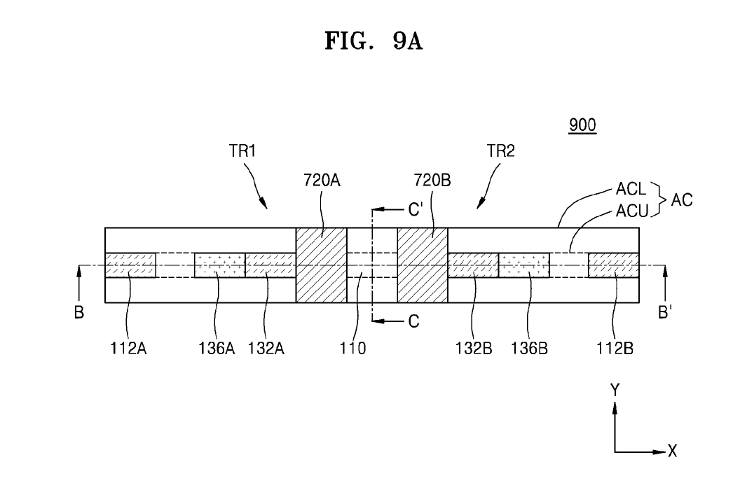

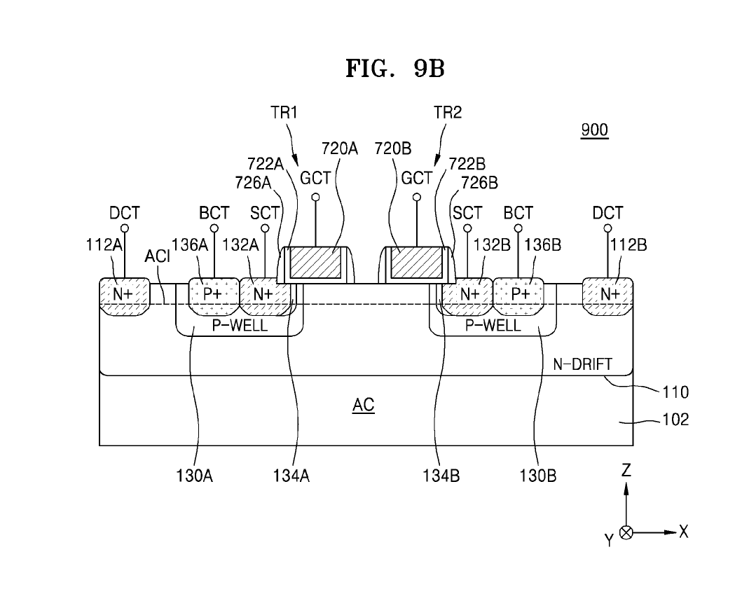

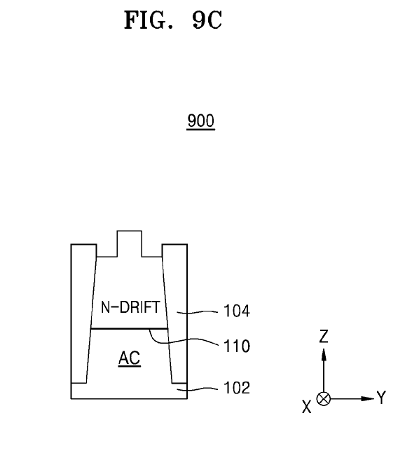

FIGS. 9A, 9B and 9C are diagrams illustrating a semiconductor device 900, according to another embodiment of the inventive concept. FIG. 9A is a plan view of main elements of the semiconductor device 900. FIG. 9B is a cross-sectional view of a line B-B′ of FIG. 9A. FIG. 9C is a cross-sectional view of a line C-C′ of FIG. 9A.

The semiconductor device 900 illustrated in FIGS. 9A through 9C generally includes the same configuration as that of the semiconductor device 700 described with reference to FIGS. 7A through 7C. However, in the semiconductor device 900, the third body contact region 736 is not formed between the first gate 720A and the second gate 720B in the drift region 110. The drift region 110 extends between the first gate 720A and the second gate 720B.

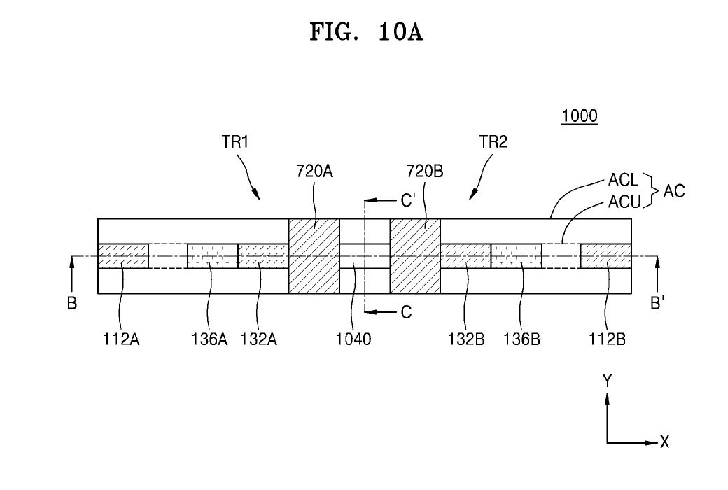

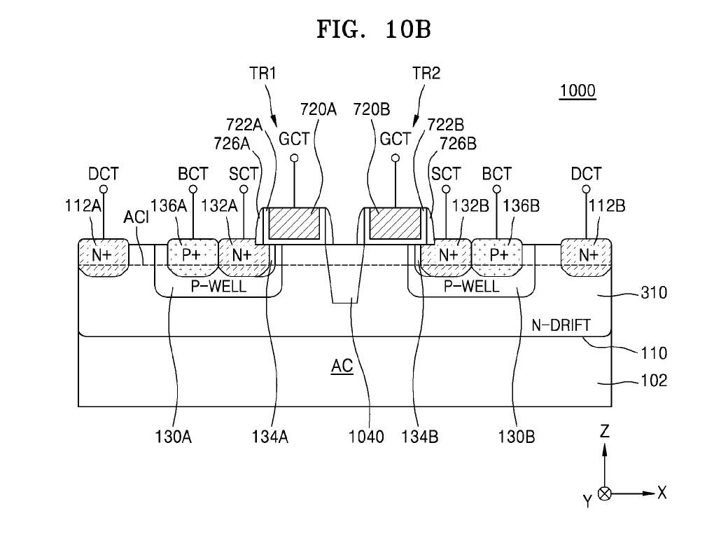

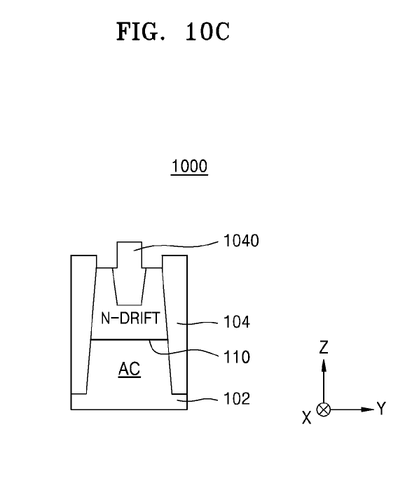

FIGS. 10A, 10B and 10C are diagrams illustrating a semiconductor device 1000, according to another embodiment of the inventive concept. The semiconductor device 1000 includes a device isolation film having a reciprocally symmetrical shape and partitioning LDMOS transistors between two adjacent LDMOS transistors. FIG. 10A is a plan view of main elements of the semiconductor device 1000. FIG. 10B is a cross-sectional view of a line B-B′ of FIG. 10A. FIG. 10C is a cross-sectional view of a line C-C′ of FIG. 10A. The same reference numerals denote the same elements in FIGS. 10A through 10C and FIGS. 1A through 9C, and thus detailed descriptions thereof are omitted.

The semiconductor device 1000 generally includes the same configuration as that of the semiconductor device 900 described with reference to FIGS. 9A through 9C. However, in the semiconductor device 1000, a device isolation film 1040 is formed in a region between the first gate 720A and the second gate 720B in the drift region 110. The first LDMOS transistor TR1 and the second LDMOS transistor TR2 are partitioned by the device isolation film 1040.

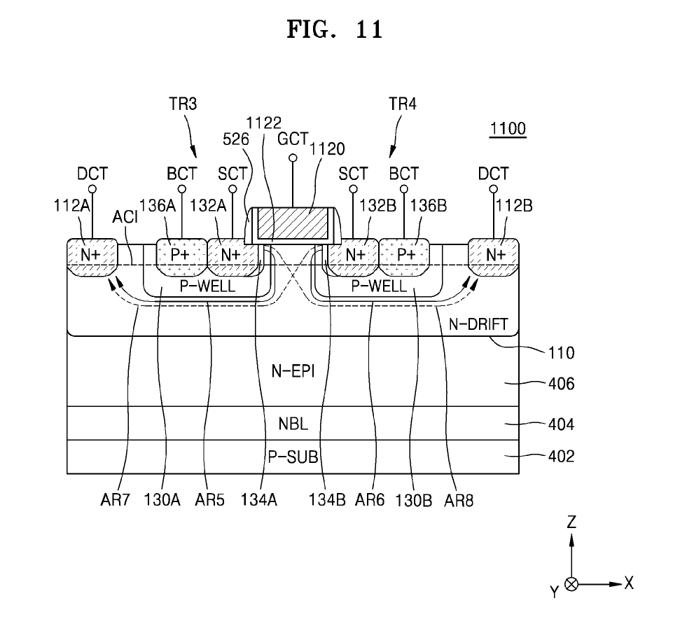

FIG. 11 is a cross-sectional view illustrating a semiconductor device 1100, according to another embodiment of the inventive concept. Semiconductor device 1100 includes planar type LDMOS transistors implemented on the bulk substrate 402. The same reference numerals denote the same elements in FIG. 11 and FIGS. 1A through 10C, and thus detailed descriptions thereof are omitted.

Referring to FIG. 11, the semiconductor device 1100 includes the bulk substrate 402, the buried layer 404, and the epitaxial layer 406 in the same manner as described with reference to FIG. 4. A pair of planar type LDMOS transistors TR3 and TR4 having a similar structure as described with reference to FIGS. 5A through 5C are formed on the epitaxial layer 406. However, a gate insulating film 1122 covering an upper surface of the drift region 110 and a planar type common gate 1120 are formed in the drift region 110. The pair of planar type LDMOS transistors TR3 and TR4 share the planar type common gate 1120 and have a reciprocally symmetrical shape with respect to the planar type common gate 1120.

Similarly to the semiconductor device 500 illustrated in FIGS. 5A through 5C, in the semiconductor device 1100 illustrated in FIG. 11, electrons may move to the first drain region 112A and the second drain region 112B from the first source region 132A and the second source region 132B through each of channel paths formed in the upper fin active regions ACU. That is, in the same manner as indicated by the arrows AR1 and AR2 of FIG. 5B, a main current flow path from the first source region 132A and the second source region 132B respectively to the first drain region 112A and the second drain region 112B via the drift region 110 along arrows AR5 and AR6 is formed, and in the same manner as indicated in the arrows AR3 and AR4 of FIG. 5B, an auxiliary current flow path crossing to the first drain region 112A and to the second drain region 112B included in the first LDMOS transistor TR1 and the second LDMOS transistor TR2 respectively from the second source region 132B and the first source region 132A along arrows AR7 and AR8 is formed. Accordingly, resistance is further reduced in the drift region 110.

FIG. 11 illustrates a structure in which a pair of planar type LDMOS transistors having a similar structure to that of the semiconductor device 500 described with reference to FIGS. 5A through 5C is formed on the epitaxial layer 406, but the inventive concept is not limited thereto. For example, in other embodiments a planar type LDMOS transistor having a similar structure to those of the semiconductor devices 600, 700, 800, 900, and 1000 described with reference to FIGS. 6 through 10C, or one of structures modified and changed in various ways within the inventive concept therefrom, may be formed on the epitaxial layer 406.

In the semiconductor device 1100 illustrated in FIG. 11, since the first source region 132A and the first body contact region 136A, and the second source region 132B and the second body contact region 136B, are formed in the drift region 110, the specific on-resistance Rsp formed between the common gate 1120 and the first drain region 112A, and between the common gate 1120 and the second drain region 112B, is reduced in the drift region 110. The first shallow well region 130A and the second shallow well region 130B are present between a corner portion of the planar type common gate 1120 and the drift region 110 so that the planar type common gate 1120 and the drift region 110 do not directly contact each other. Thus, an electric field concentration phenomenon that might occur at the corner portions of the planar type common gate 1120 are prevented, and the substrate current Isub is reduced. The specific on-resistance Rsp formed between the planar type common gate 1120 and the first drain region 112A, and between the planar type common gate 1120 and the second drain region 112B, are reduced in the drift region 110, and an area occupied by one LDMOS transistor is reduced.

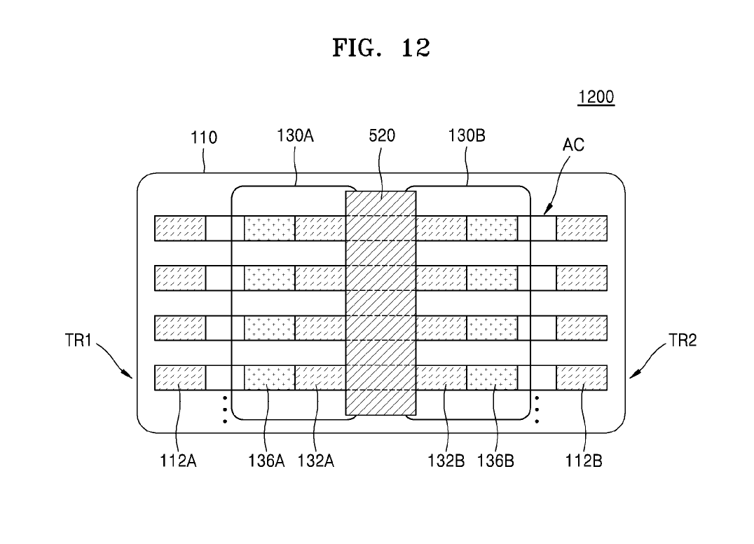

FIG. 12 is a plan view illustrating a semiconductor device 1200, according to another embodiment of the inventive concept.

The semiconductor device 1200 generally includes similar elements to those of the semiconductor device 500 described with reference to FIGS. 5A through 5C. However, the semiconductor device 1200 illustrated in FIG. 12 includes one drift region 110, and the first shallow well region 130A and the second shallow well region 130B that are formed in the drift region 110. The first shallow well region 130A and the second shallow well region 130B that are formed in the drift region 110 are shared by the plurality of active regions AC. The one common gate 520 is formed in the plurality of active regions AC. The first LDMOS transistor TR1 and the second LDMOS transistor TR2 having the generally same configuration as described with reference to FIGS. 5A through 5C may be implemented in the plurality of active regions AC.

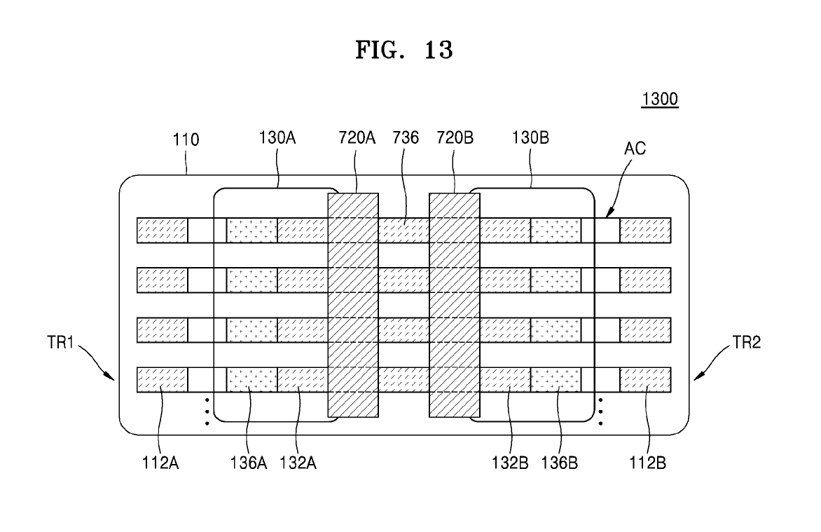

FIG. 13 is a plan view illustrating a semiconductor device 1300, according to another embodiment of the inventive concept.

The semiconductor device 1300 includes generally similar elements to those of the semiconductor device 700 illustrated in FIGS. 7A through 7C. However, the semiconductor device 1300 of FIG. 13 includes one drift region 110 and the first shallow well region 130A and the second shallow well region 130B that are formed in the drift region 110. The first shallow well region 130A and the second shallow well region 130B that are formed in the drift region 110 are shared by the plurality of active regions AC. The first gate 720A and the second gate 720B that are spaced apart from each other are formed in the plurality of active regions AC. Each of the plurality of active regions AC includes the third body contact region 736 formed between the first gate 720A and the second gate 720B in the drift region 110. The first LDMOS transistor TR1 and the second LDMOS transistor TR2 having the generally same configuration as described with reference to FIGS. 7A through 7C may be implemented in the plurality of active regions AC.

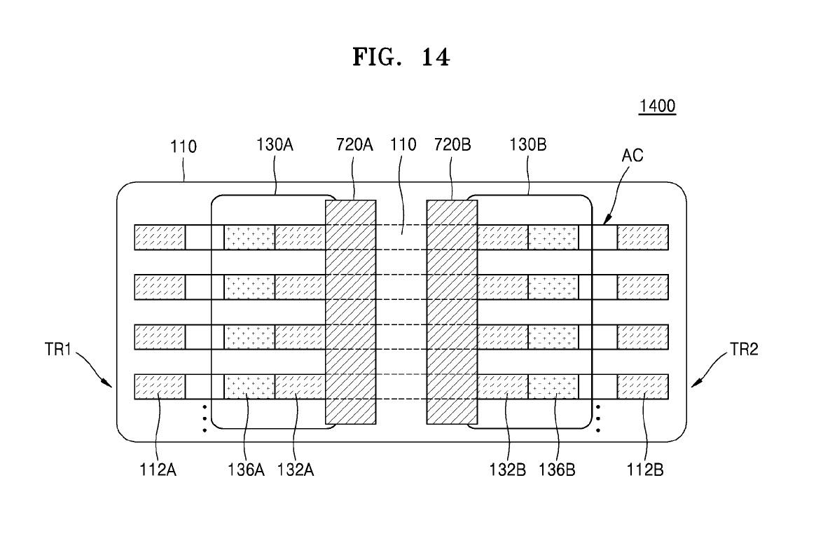

FIG. 14 is a plan view illustrating a semiconductor device 1400, according to another embodiment of the inventive concept.

The semiconductor device 1400 includes generally similar elements to those of the semiconductor device 900 illustrated in FIGS. 9A through 9C. However, the semiconductor device 1400 of FIG. 14 includes one drift region 110 and the first shallow well region 130A and the second shallow well region 130B that are formed in the drift region 110. The first shallow well region 130A and the second shallow well region 130B that are formed in the drift region 110 are shared by the plurality of active regions AC. The first gate 720A and the second gate 720B that are spaced apart from each other are formed in the plurality of active regions AC. The drift region 110 extends between the first gate 720A and the second gate 720B in the plurality of active regions AC. The first LDMOS transistor TR1 and the second LDMOS transistor TR2 having the generally same configuration as described with reference to FIGS. 9A through 9C may be implemented in the plurality of active regions AC.

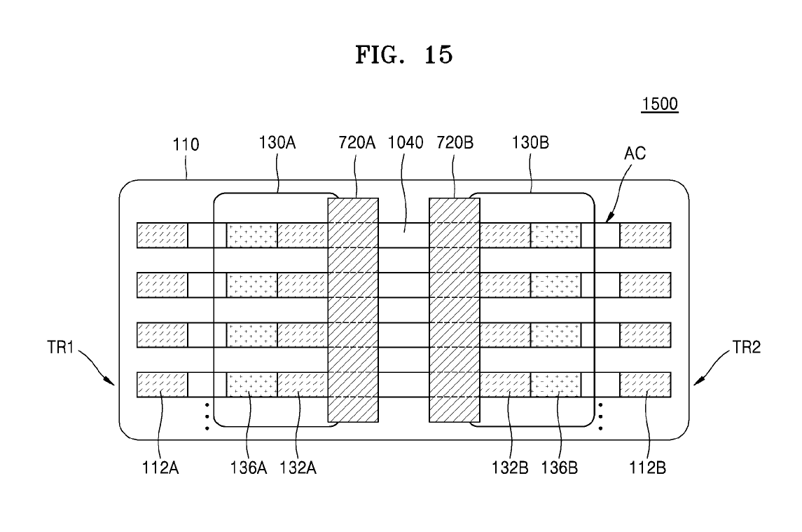

FIG. 15 is a plan view of a semiconductor device 1500, according to another embodiment of the inventive concept.

The semiconductor device 1500 includes generally similar elements to those of the semiconductor device 1000 illustrated in FIGS. 10A through 10C. However, the semiconductor device 1500 of FIG. 15 includes one drift region 110 and the first shallow well region 130A and the second shallow well region 130B that are formed in the drift region 110. The first shallow well region 130A and the second shallow well region 130B that are formed in the drift region 110 are shared by the plurality of active regions AC. The first gate 720A and the second gate 720B that are spaced apart from each other are formed in the plurality of active regions AC. The device isolation film 1040 is formed in the drift region 110 between the first gate 720A and the second gate 720B in the plurality of active regions AC. The first LDMOS transistor TR1 and the second LDMOS transistor TR2 having the generally same configuration as described with reference to FIGS. 10A through 10C may be implemented in the plurality of active regions AC. The first LDMOS transistor TR1 and the second LDMOS transistor TR2 is partitioned by the device isolation film 1040 in the plurality of active regions AC.

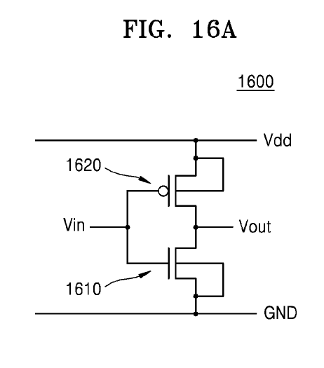

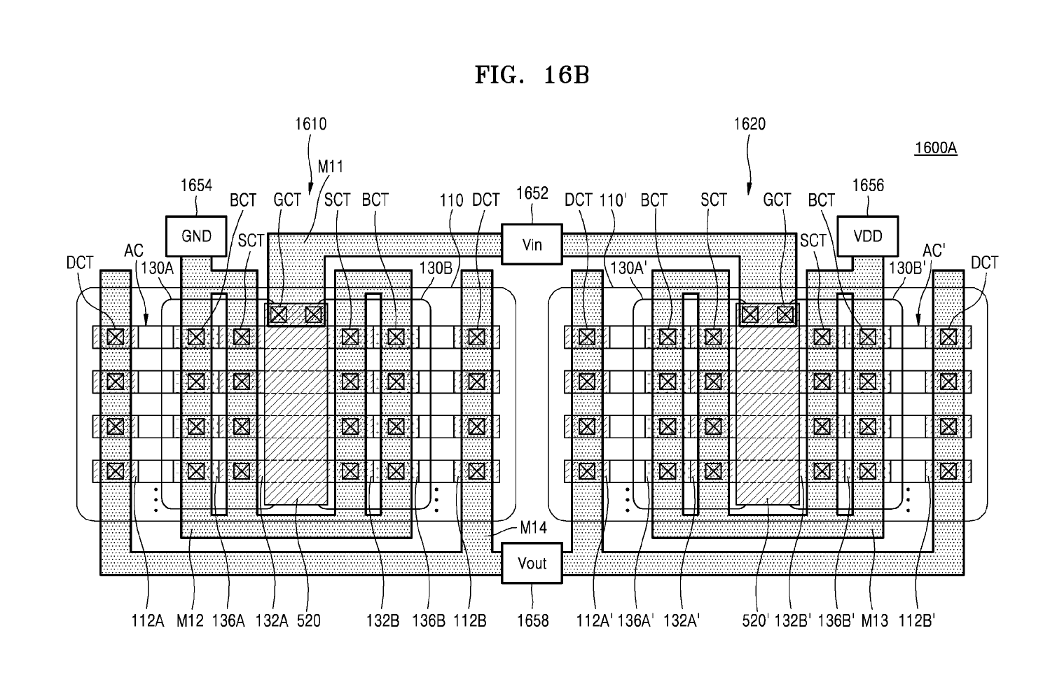

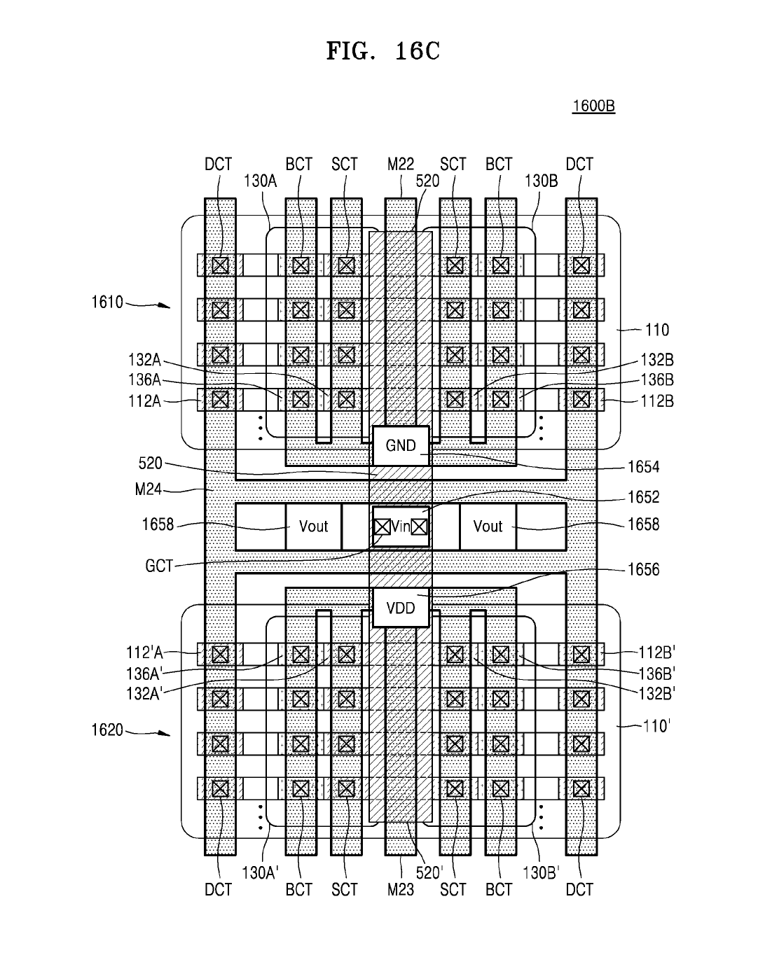

FIG. 16A is an equivalent circuit diagram illustrating a CMOS inverter 1600 including a semiconductor device, according to another embodiment of the inventive concept.

The CMOS inverter 1600 is configured as an inversion circuit including an N-channel LDMOS transistor 1610 and a P-channel LDMOS transistor 1620. When an input signal Vin of the CMOS inverter 1600 is high, the P-channel LDMOS transistor 1620 is turned off, and the N-channel LDMOS transistor 1610 is turned on, a low signal is output as an output signal Vout. To the contrary, when the input signal Vin of the CMOS inverter 1600 is low, the P-channel LDMOS transistor 1620 is turned on, and the N-channel LDMOS transistor 1610 is turned off, a high signal is output as the output signal Vout.

FIG. 16B is an example illustrating a layout of an inverter 1600A for implementing the CMOS inverter 1600 shown in FIG. 16A including an equivalent circuit.

FIG. 16B illustrates the inverter 1600A including the N-channel LDMOS transistor 1610 and the P-channel LDMOS transistor 1620 having a structure of the semiconductor device 1200 illustrated in FIG. 12 or a structure similar to the structure of the semiconductor device 1200. The N-channel LDMOS transistor 1610 is configured as N-channel LDMOS transistors having the same or similar structure as that of the semiconductor device 1200 illustrated in FIG. 12. The P-channel LDMOS transistor 1620 is configured as LDMOS transistors having the same or similar structure as that of the semiconductor device 1200 illustrated in FIG. 12, except for including P-channel LDMOS transistors. Elements denoted by reference numerals with a prime ′ among elements of the P-channel LDMOS transistor 1620 correspond to elements denoted by the same reference numerals among elements of the N-channel LDMOS transistor 1610. Among these elements, elements having a specific conductive type and denoted by a reference numeral with a prime ′ have a conductive type opposite to that of elements denoted by reference numerals without the prime ′.

The common gate 520 of the N-channel LDMOS transistor 1610 and a common gate 520′ of the P-channel LDMOS transistor 1620 are connected to the gate contact terminals GCT, and an input signal terminal 1652 through a wiring M11 connected to the gate contact terminals GCT.

The first source regions 132A, the second source regions 132B, the first body contact regions 136A, and the second body contact regions 136B of the N-channel LDMOS transistor 1610 are connected to the source contact terminals SCT, the body contact terminals BCT, and a reference electric potential terminal 1654 through a wiring M12 connected to the source contact terminals SCT and the body contact terminals BCT.

The first source regions 132A′, second source regions 132B′, first body contact regions 136A′, and second body contact regions 136B′ of the P-channel LDMOS transistor 1620 are connected to the source contact terminals SCT, the body contact terminals BCT, and a supply terminal 1656 through a wiring M13 connected to the source contact terminals SCT and the body contact terminals BCT.

The first drain regions 112A and the second drain regions 112B of the N-channel LDMOS transistor 1610, and the first drain regions 112A′ and the second drain regions 112B′ of the P-channel LDMOS transistor 1620 are connected to the drain contact terminals DCT and an output terminal 1658 through a wiring M14 connected to the drain contact terminals DCT.

FIG. 16C is another example illustrating a layout of an inverter 1600B for implementing the CMOS inverter 1600 of FIG. 16A including an equivalent circuit.

Similarly to the inverter 1600A illustrated in FIG. 16B, FIG. 16C illustrates the inverter 1600B including the N-channel LDMOS transistor 1610 and the P-channel LDMOS transistor 1620 having a structure of the semiconductor device 1200 illustrated in FIG. 12 or a structure similar to the structure of the semiconductor device 1200. However, in the inverter 1600B illustrated in FIG. 16C, the common gate 520 of the N-channel LDMOS transistor 1610 and a common gate 520′ of the P-channel LDMOS transistor 1620 are integrally connected to each other. The integrally connected common gates 520 and 520′ are connected to the input signal terminal 1652 through the gate contact terminals GCT.

The first source regions 132A, the second source regions 132B, the first body contact regions 136A, and the second body contact regions 136B of the N-channel LDMOS transistor 1610 are connected to the source contact terminals SCT, the body contact terminals BCT, and the reference electric potential terminal 1654 through a wiring M22 connected to the source contact terminals SCT and the body contact terminals BCT.

The first source regions 132A′, the second source regions 132B′, the first body contact regions 136A′, and the second body contact regions 136B′ of the P-channel LDMOS transistor 1620 are connected to the source contact terminals SCT, the body contact terminals BCT, and the supply terminal 1656 through a wiring M23 connected to the source contact terminals SCT and the body contact terminals BCT.

The first drain regions 112A and the second drain regions 112B of the N-channel LDMOS transistor 1610, and the first drain regions 112A′ and the second drain regions 112B′ of the channel LDMOS transistor 1620 are connected to the drain contact terminals DCT and the output terminal 1658 through a wiring M24 connected to the drain contact terminals DCT.

FIGS. 16B and 16C illustrate a case where the N-channel LDMOS transistor 1610 and the P-channel LDMOS transistor 1620 of the inverters 1600A and 1600B have a structure corresponding to the semiconductor device 500 illustrated in FIGS. 5A through 5C, but the inventive concept is not limited thereto. For example, in other embodiments the N-channel LDMOS transistor 1610 and the P-channel LDMOS transistor 1620 of the inverters 1600A and 1600B may have a structure of one of the semiconductor devices 100, 200, 300, 400, 500, 600, 700, 800, 900, 1000, 1100, 1200, 1300, 1400, and 1500 according to the embodiments described with reference to FIGS. 1A through 15, or one selected from structures modified and changed within the inventive concept therefrom.

The CMOS inverters 1600, 1600A, and 1600B illustrated in FIGS. 16A through 16C reduce area occupied by the N-channel LDMOS transistor 1610 and the P-channel LDMOS transistor 1620 so that the CMOS inverters 1600, 1600A, and 1600B may be preferably used in a highly scaled integrated circuit device, and an improved electrical characteristic and reliability may be provided.

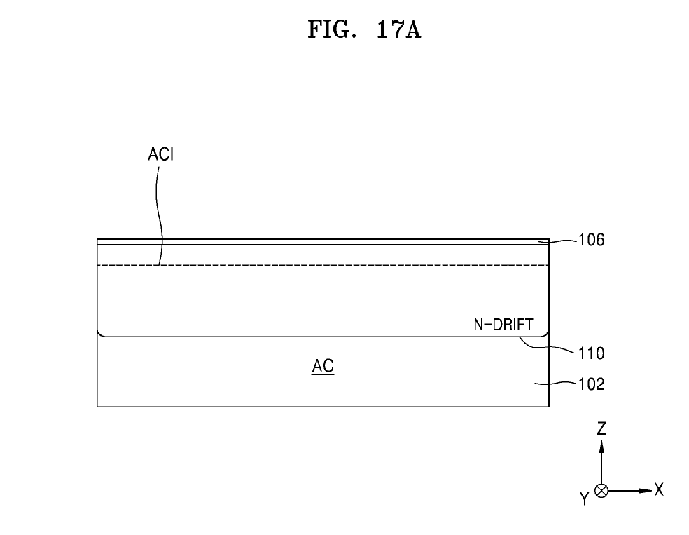

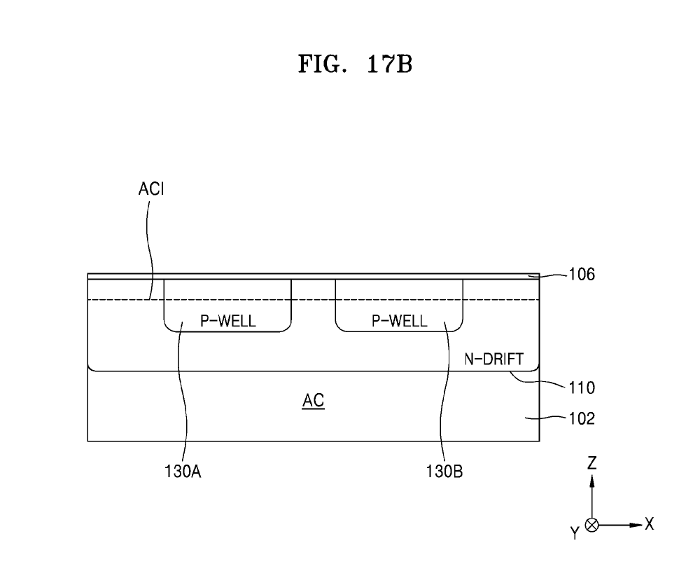

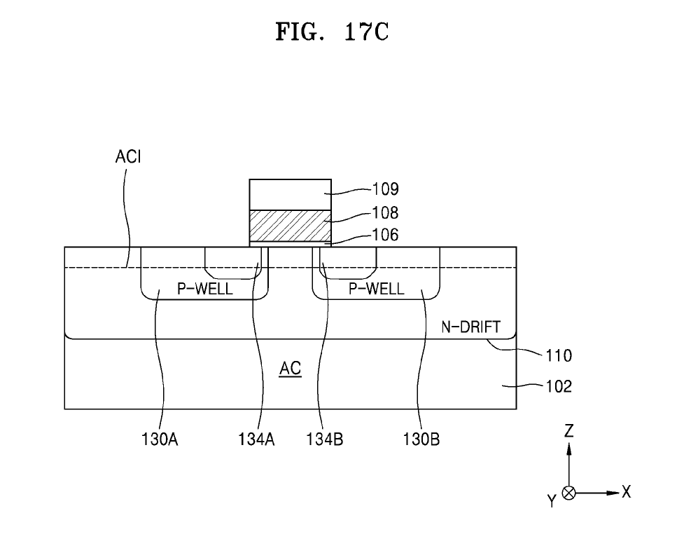

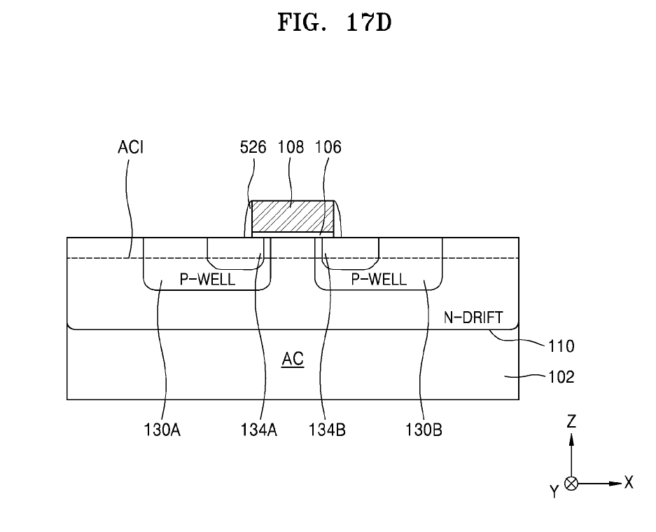

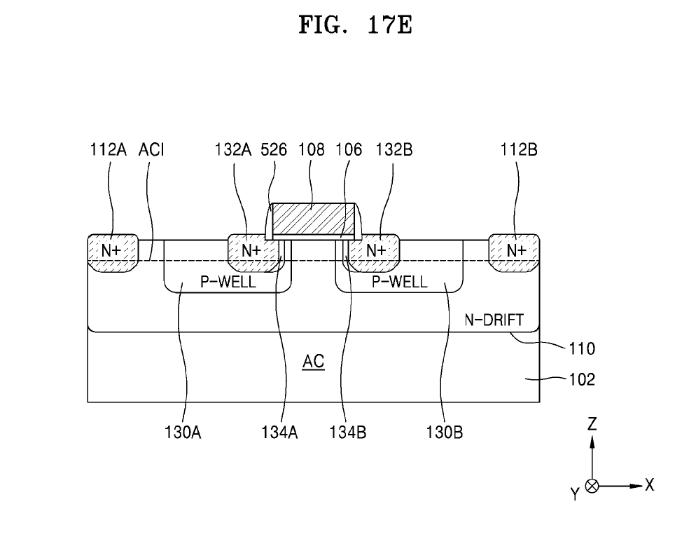

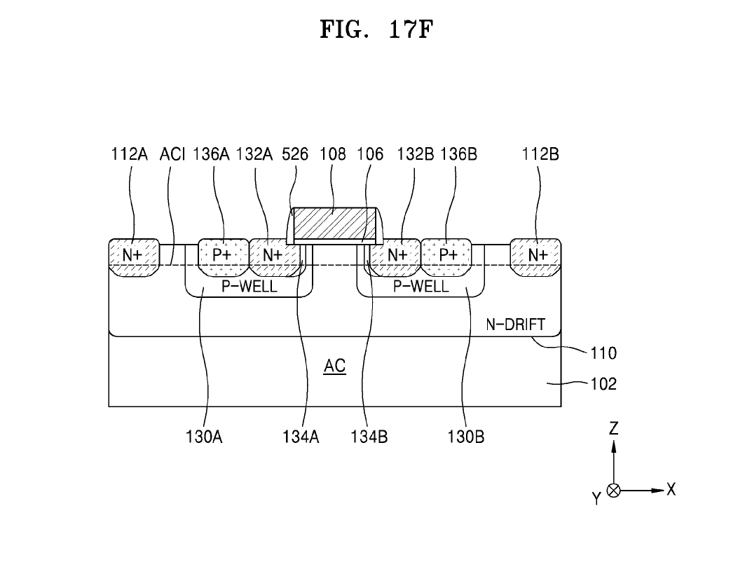

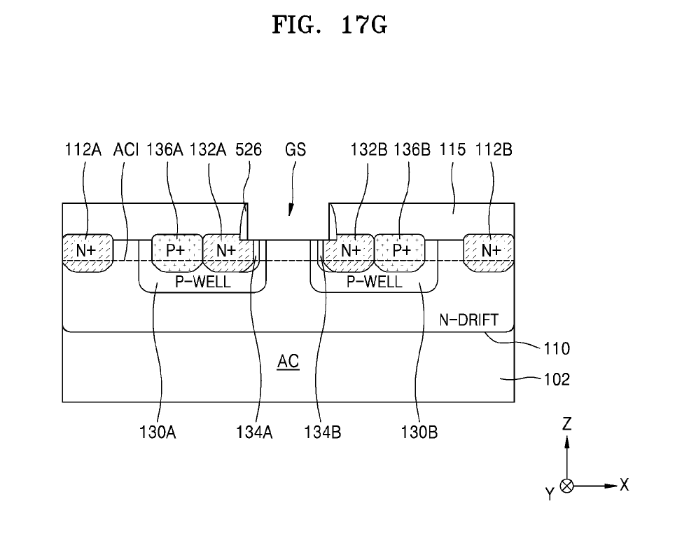

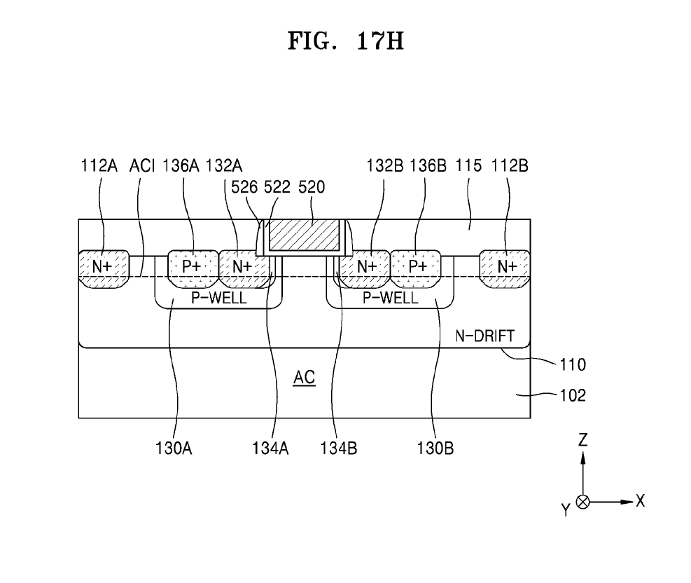

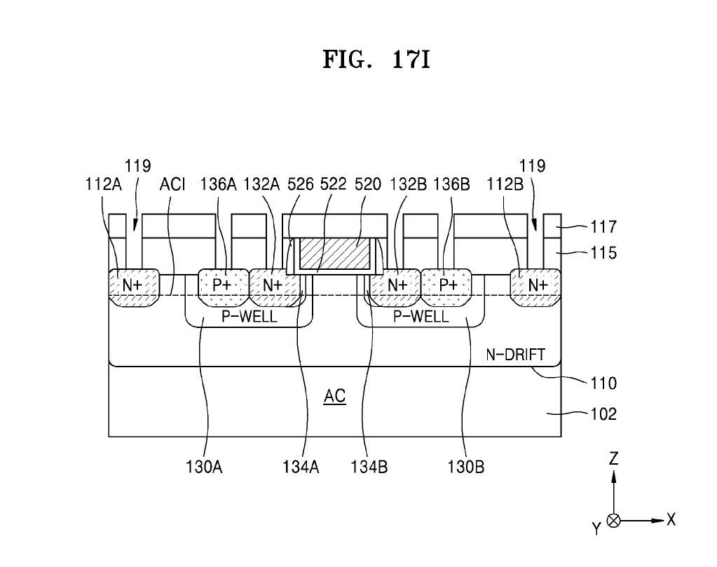

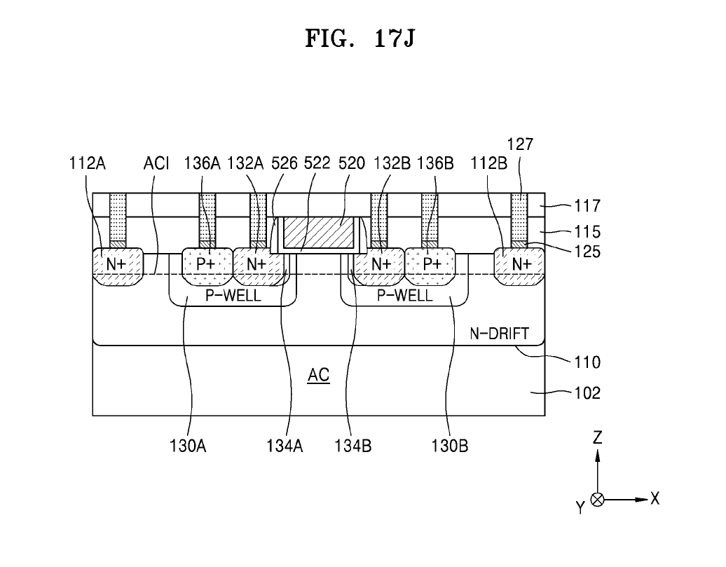

FIGS. 17A, 17B, 17C, 17D, 17E, 17F, 17G, 17H, 17I and 17J are cross-sectional views illustrating sequentially a method of manufacturing the semiconductor device 500 illustrated in FIGS. 5A through 5C, according to embodiments of the inventive concept. The same reference numerals denote the same elements in FIGS. 17A through 17J and FIGS. 1A through 5C, and thus detailed descriptions thereof are omitted.

Referring to FIG. 17A, after the substrate 102 including the fin type active region AC is prepared, an insulating film 106 is formed in an exposed surface of the active region AC, and the drift region 110 is formed in the active region AC.

The active region AC includes the lower fin active region ACL having the first width W1 illustrated in FIG. 1C and the upper fin active region ACU integrally connected to the lower fin active region ACL and having the second width W2 smaller than the first width W1. In FIG. 17A, a level of a boundary between the lower fin active region ACL and the upper fin active region ACU is indicated in a broken line ACI.

The insulating film 106 may act to protect the substrate 102 when an ion injection process is performed on the substrate 102. In some embodiments, the insulation film 106 may be formed as an oxide film but is not limited thereto.

In some embodiments, an N type impurity may be doped to form the drift region 110 necessary for an N-channel LDMOS transistor.

Referring to FIG. 17B, the first shallow well region 130A and the second shallow well region 130B are formed in the drift region 110.

In some embodiments, a P type impurity may be doped in a partial region of the drift region 110 to form the first shallow well region 130A and the second shallow well region 130B. The first shallow well region 130A and the second shallow well region 130B may be formed to have a smaller depth than that of the drift region 110.

Referring to FIG. 17C, after a dummy gate 108 covering the insulating film 106 is formed on the active region AC, the first extension region 134A and the second extension region 134B are respectively formed in the first shallow well region 130A and the second shallow well region 130B at both sides of the dummy gate 108.

The dummy gate 108 may have a line shape extending in a direction crossing the active region AC.

In some embodiments, to form the dummy gate 108, after a dummy gate layer is formed on the insulating film 106 and a mask pattern 109 is formed on the dummy gate layer, a process of etching the dummy gate layer may be performed by using the mask pattern 109 as an etching mask. During the process of etching the dummy gate layer, the insulating film 106 may be removed around the dummy gate 108 and the active region AC may be exposed around the dummy gate 108.

The dummy gate 108 may be formed of polysilicon, and the mask pattern 109 may be formed of silicon nitride but the inventive concept is not limited thereto.

To form the first extension region 134A and the second extension region 134B, a tilt ion injection process may be used to dope the active region AC with the N type impurity. In some embodiments, an ion injection for forming a halo ion injection region (not shown) in the active region AC may be performed during the ion injection process for forming the first extension region 134A and the second extension region 134B.

Referring to FIG. 17D, after the mask pattern 109 covering the dummy gate 108 is removed, the insulating spacer 526 is formed in both side walls of the dummy gate 108.

To form the insulating spacer 526, after a spacer insulating film covering an upper surface and both side walls of the dummy gate 108 and the insulating film 106 are formed, the spacer insulating film is etched until the upper surface of the dummy gate 108 is exposed so that the insulating spacer 526 covering both side walls of the dummy gate 108 remains.

The insulating spacer 526 may be formed of silicon nitride, silicon oxynitride, or a combination of these.

Referring to FIG. 17E, the first drain region 112A and the second drain region 112B that are surrounded by the drift region 110, and the first source region 132A and the second source region 132B that are respectively surrounded by the first shallow well region 130A and the second shallow well region 130B, are formed in the active region AC.

To form the first drain region 112A, the second drain region 112B, the first source region 132A, and the second source region 132B, after a plurality of source/drain forming trenches are formed by etching some regions of the active region AC, a source/drain forming semiconductor layer may be formed in the plurality of source/drain forming trenches through an epitaxial growth process. The source/drain forming semiconductor layer may be formed of Si or SiC, but is not limited thereto. N+ doping may be simultaneously performed during an epitaxial growth of the source/drain forming semiconductor layer. Accordingly, the first drain region 112A, the second drain region 112B, the first source region 132A, and the second source region 132B may be formed as N+ type semiconductor layers.

Each of the first drain region 112A, the second drain region 112B, the first source region 132A, and the second source region 132B may have a raised source/drain (RSD) structure having an upper surface at a higher level than that of the upper surface of the active region AC.

Referring to FIG. 17F, the first body contact region 136A adjacent to the first source region 132A and the second body contact region 136B adjacent to the second source region 132B are respectively formed in the first shallow well region 130A and the second shallow well region 130B in the active region AC.

To form the first body contact region 136A and the second body contact region 136B, after a plurality of body contact forming trenches are formed by etching some regions of the active region AC, a body contact forming semiconductor layer may be formed in the plurality of body contact forming trenches through the epitaxial growth process. The body contact forming semiconductor layer may be formed of SiGe, but is not limited thereto. P+ doping may be simultaneously performed during an epitaxial growth of the body contact forming semiconductor layer. Accordingly, the first body contact region 136A and the second body contact region 136B may be formed as P+ type semiconductor layers.

The first body contact region 136A and the second body contact region 136B may have an RSD structure having an upper surface at a higher level than that of the upper surface of the active region AC.

In some embodiments, a process of additionally doping the first drain region 112A, the second drain region 112B, the first source region 132A, and the second source region 132B with the N+ impurity may be selectively performed, and a process of additionally doping the first body contact region 136A and the second body contact region 136B with the P+ impurity may be selectively performed. Such additional doping processes are performed, thereby reducing resistances in the first drain region 112A, the second drain region 112B, the first source region 132A, the second source region 132B, the first body contact region 136A, and the second body contact region 136B.

Referring to FIG. 17G, after an inter-gate insulating film 115 is formed around the dummy gate 108 and the insulating spacer 526, the active region AC is exposed through a gate space GS limited by the insulating spacer 526 by removing the dummy gate 108 and the insulating film 106 below the dummy gate 108.

As an example of forming the inter-gate insulating film 115, an insulating film having a sufficient thickness to cover the dummy gate 108 and the insulating spacer 526 may be formed on the active region AC. Thereafter, the inter-gate insulating film 115 having a planarized upper surface may be formed by planarizing the formed insulating film so that the dummy gate 108 may be exposed. In some embodiments, the inter-gate insulating film 115 may be formed of an oxide film, a nitride film, or a combination of these. In some embodiments, the inter-gate insulating film 115 may be formed as a tetra ethyl ortho silicate (TEOS) film. In other embodiments, the inter-gate insulating film 115 may be formed as an ultra low K (ULK) having an ultra low dielectric constant K of about 2.2˜about 2.4, for example, one selected from an SiOC film and an SiCOH film.

Referring to FIG. 17H, the gate insulating film 522 and the common gate 520 are sequentially formed in the gate space GS (see FIG. 17G).

In some embodiments, before the gate insulating film 522 is formed in the gate space GS, a process of forming an interface film (not shown) on a surface of the active region AC exposed through the gate space GS may be further performed. To form the interface film, a process of oxidizing a part of the active region AC exposed in the gate space GS may be performed. The interface film may act to prevent an interface defect between the gate insulating film 522 formed on the interface film and an active region ACT below the interface film. In some embodiments, the interface film may be formed of a silicon oxide film, a silicon oxynitride film, a silicate film, or a combination of these.

The gate insulating film 522 may be formed of a silicon oxide film, a high dielectric film, or a combination of these. The high dielectric film may be formed of a material having a higher dielectric constant than that of the silicon oxide film. For example, the gate insulting film 522 may have a dielectric constant in the range of about 10 through about 25.

The common gate 520 may be formed of metal, conductive metal nitride, or a combination of these. In some embodiments, the common gate 520 may have a structure in which a conductive metal nitride layer, a metal layer, a conductive capping layer, and a gap-fill metal layer are sequentially stacked. Each of the metal nitride layer and the metal layer may include at least one metal selected from Ti, Ta, W, Ru, Nb, and Hf. The metal nitride layer and the metal layer may be formed by ALD, MOALD, or MOCVD. The conductive capping layer may act as a protection film preventing a surface of the metal layer from being oxidized. The conductive capping layer may act as a wetting layer used to easily deposit another conductive layer on the metal layer. The conductive capping layer may be formed of metal nitride, for example, TiN, TaN, or a combination of these but is not limited thereto. The gap-fill metal layer may be formed of a W film. The gap-fill metal layer may be formed through ALD, CVD, or PVD process.

Referring to FIG. 17I, after an insulating film 117 covering the inter-gate insulating film 115 and the common gate 520 is formed, a plurality of contact holes 119 exposing the first drain region 112A, the second drain region 112B, the first source region 132A, the second source region 132B, the first body contact region 136A, and the second body contact region 136B are formed.

Although not shown, the plurality of contact holes 119 may include a contact hole exposing the common gate 520.

In some embodiments, the insulating film 117 may be formed of an oxide film, a nitride film, or a combination of these. In some embodiments, the insulating film 117 may include the same material as that of the material of the inter-gate insulating film 115.

Referring to FIG. 17J, after a metal silicide film 125 is formed on a surface of each of the first drain region 112A, the second drain region 112B, the first source region 132A, the second source region 132B, the first body contact region 136A, and the second body contact region 136B that are exposed through the plurality of contact holes 119, a plurality of contact plugs 127 filling the plurality of contact holes 119 are formed on the metal silicide film 125.

Although not shown, a metal silicide film such as metal silicide film 125 may be formed covering the surface of the common gate 520 in contact holes such as contact holes 119 exposing the common gate 520, and contact plugs such as contact plugs 127 may be formed filling such contact holes exposing the common gate 520.

In some embodiments, the metal silicide film 125 may be formed of nickel silicide, cobalt silicide, or a combination of these, but is not limited thereto.

In some embodiments, the plurality of contact plugs 127 may include a conductive bather film and a metal plug. The conductive bather film may be formed of Ti, Ta, TiN, TaN, or a combination of these. The metal plug may be formed of W.

Thereafter, devices performing a desired function may be implemented by forming wirings (not shown) selectively connected to the plurality of contact plugs 127.

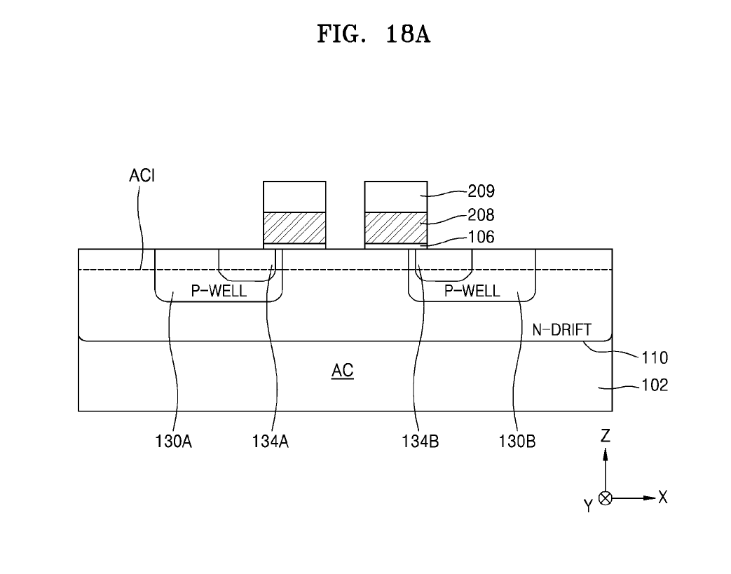

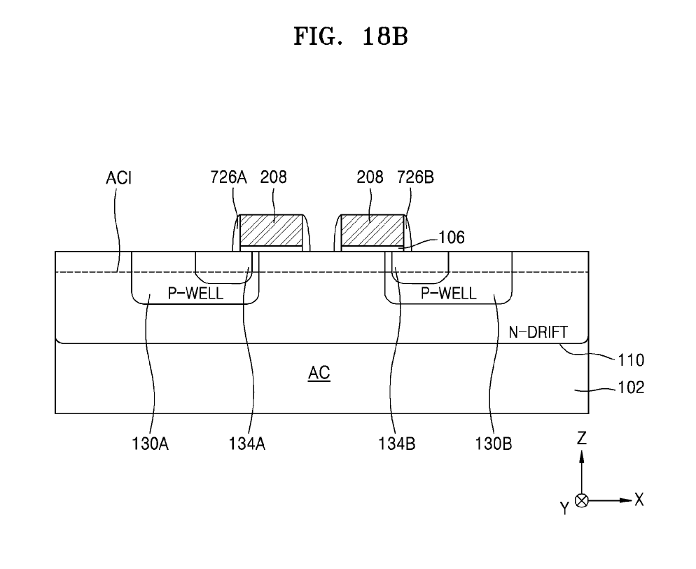

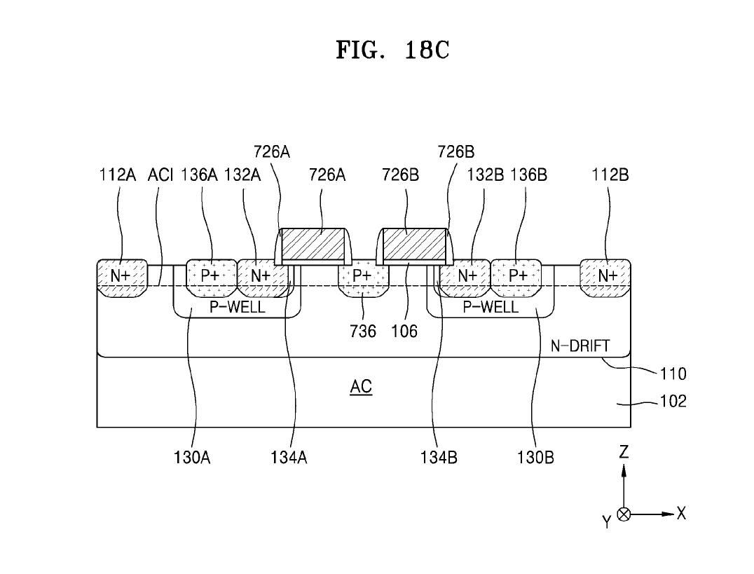

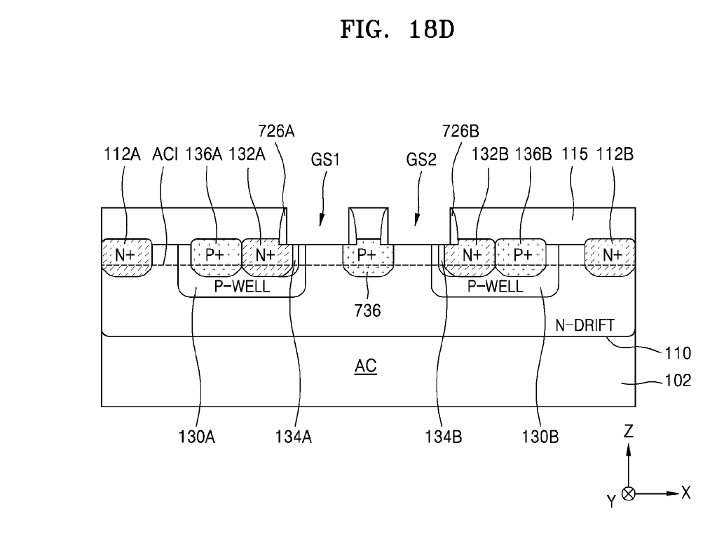

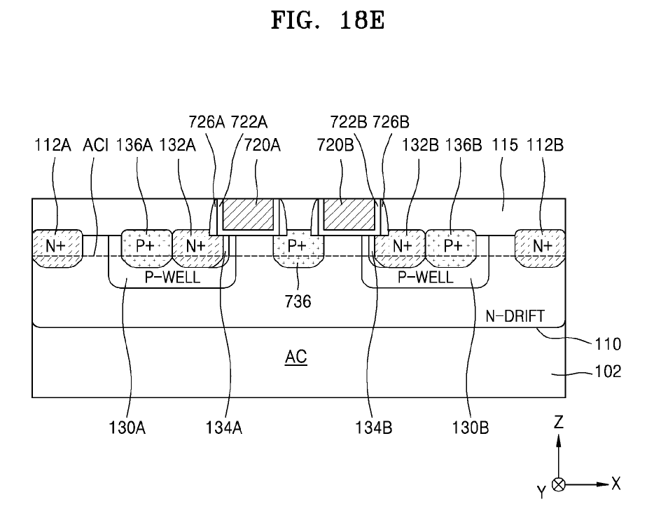

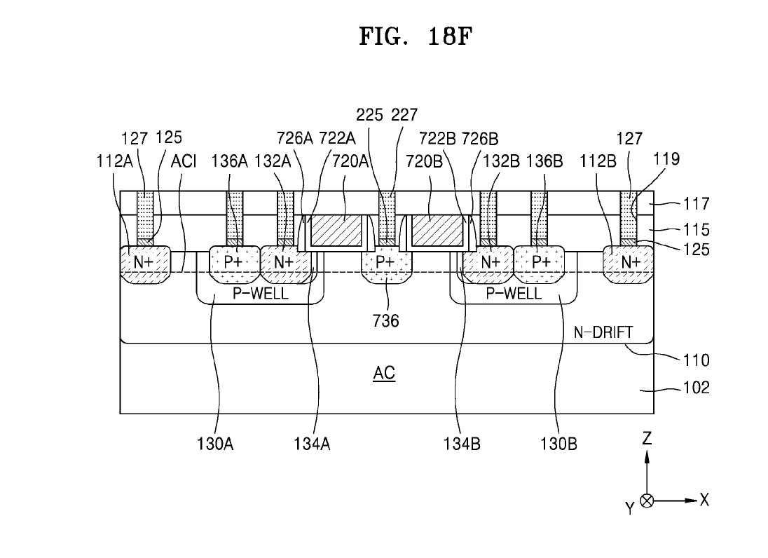

FIGS. 18A, 18B, 18C, 18D, 18E, and 18F are cross-sectional views illustrating sequentially a method of manufacturing the semiconductor device 700 illustrated in FIGS. 7A through 7C, according to embodiments of the inventive concept. The same reference numerals denote the same elements in FIGS. 18A through 18F and FIGS. 1A through 17J, and thus detailed descriptions thereof are omitted.

Referring to FIG. 18A, the drift region 110 and the first shallow well region 130A and the second shallow well region 130B are formed in the fin type active region AC of the substrate 102 by performing processes described with reference to FIGS. 17A and 17B.

Thereafter, in the same manner as described with reference to FIG. 17C, a plurality of dummy gates 208 covering the insulating film 106 are formed on the active region AC, the first extension region 134A and the second extension region 134B are respectively formed in the first shallow well region 130A and the second shallow well region 130B at one side of each of the plurality of dummy gates 208.

The plurality of dummy gates 208 may have a line shape extending in a direction crossing the active region AC.

In some embodiments, to form the plurality of dummy gates 208, after a dummy gate layer is formed on the insulating film 106 and a plurality of mask patterns 209 are formed on the dummy gate layer, a process of etching the dummy gate layer may be performed by using the mask pattern 209 as an etching mask. During the process of etching the dummy gate layer, the insulating film 106 may be removed around the plurality of dummy gates 208 and the active region AC may be exposed around the plurality of dummy gates 208.

The plurality of dummy gates 208 may be formed of polysilicon, and the plurality of mask patterns 209 may be formed of silicon nitride, but the inventive concept is not limited thereto.

Referring to FIG. 18B, after the plurality of mask patterns 209 (see FIG. 18A) are removed, in the same manner as described with respect to a process of forming the insulating spacer 526 with reference to FIG. 17D, a first insulating spacer 726A and a second insulating spacer 726B are formed on both side walls of each of the plurality of dummy gates 208.

The first insulating spacer 726A and the second insulating spacer 726B may be formed of silicon nitride, silicon oxynitride, or a combination of these.

Referring to FIG. 18C, in the same manner as described with reference to FIGS. 17E and 17F, the first drain region 112A and the second drain region 112B that are surrounded by the drift region 110, the first source region 132A and the second source region 132B that are respectively surrounded by the first shallow well region 130A and the second shallow well region 130B, the first body contact region 136A adjacent to the first source region 132A in the first shallow well region 130A, and the second body contact region 136B adjacent to the second source region 132B in the second shallow well region 130B, are formed in the active region AC.

However, during the formation of the first body contact region 136A and the second body contact region 136B, a third body contact region 736 is further formed between the first shallow well region 130A and the second shallow well region 130B in the drift region 110.

Referring to FIG. 18D, in the same manner as described with reference to FIG. 17G, after the inter-gate insulating film 115 is formed around the plurality of dummy gates 208 whose both side walls are covered by the first insulating spacer 726A and the second insulating spacer 726B, the active region AC is exposed through gate spaces GS1 and GS2 limited by the first insulating spacer 726A and the second insulating spacer 726B by removing the plurality of dummy gates 208 and the insulating film 106 below the plurality of dummy gates 208.

Referring to FIG. 18E, the first gate insulating film 722A and the first gate 720A are formed in the gate space GS1 (see FIG. 18D), and the second gate insulating film 722B and the second gate 720B are formed in the gate space GS2 (see FIG. 18D) by using processes similar to processes of forming the gate insulating film 522 and the common gate 520 described with reference to FIG. 17H.

Referring to FIG. 18F, in the same manner as described with reference to FIGS. 17I and 17J, after the insulating film 117 covering the inter-gate insulating film 115 and the first gate 720A and the second gate 720B is formed, the plurality of contact holes 119 exposing the first drain region 112A, the second drain region 112B, the first source region 132A, the second source region 132B, the first body contact region 136A, the second body contact region 136B, and the third body contact region 736 are formed.

Thereafter, in the same manner as described with reference to FIG. 17J, after the metal silicide film 125 is formed on a surface of each of the first drain region 112A, the second drain region 112B, the first source region 132A, the second source region 132B, the first body contact region 136A, and the second body contact region 136B that are exposed through the plurality of contact holes 119, the plurality of contact plugs 127 filling the plurality of contact holes 119 are formed on the metal silicide film 125. However, in the present embodiment, during the formation of the metal silicide film 125 and the plurality of contact plugs 127, a metal silicide film 225 covering a surface of the third body contact region 736 and a plurality of contact plugs 227 filling the contact holes 119 on the metal silicide film 225 are simultaneously formed.

The metal silicide film 225 and the plurality of contact plugs 227 may have the configurations as described with respect to the metal silicide film 125 and the plurality of contact plugs 127 with reference to FIG. 17I.

Thereafter, devices performing a desired function may be implemented by forming wirings (not shown) selectively connected to the plurality of contact plugs 127 and 227.

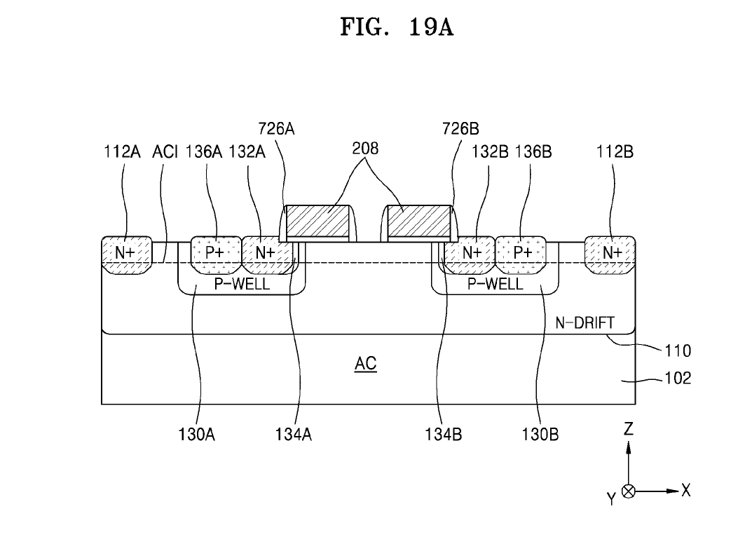

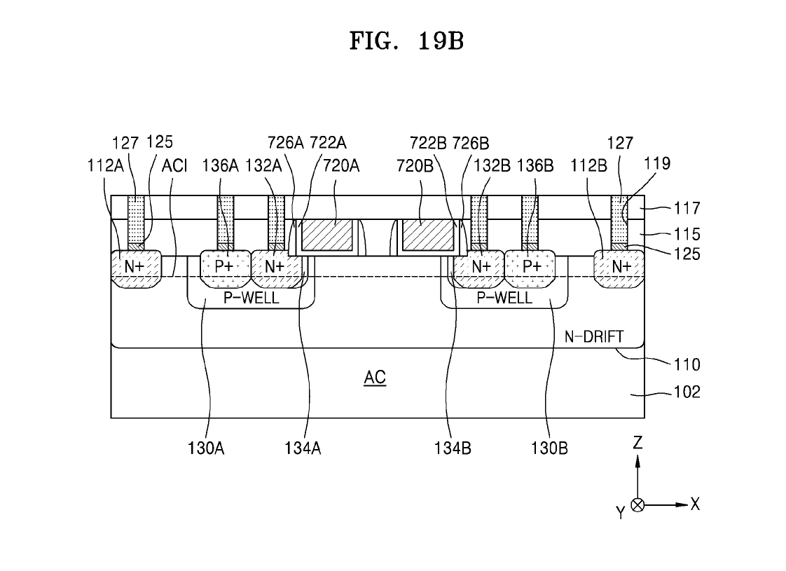

FIGS. 19A and 19B are cross-sectional views illustrating sequentially a method of manufacturing the semiconductor device 900 illustrated in FIGS. 9A through 9C, according to embodiments of the inventive concept. The same reference numerals denote the same elements in FIGS. 19A and 19B and FIGS. 1A through 18F, and thus detailed descriptions thereof are omitted.

Referring to FIG. 19A, by performing the processes described with reference to FIGS. 18A through 18C, the plurality of dummy gates 208 whose both side walls are covered by the first insulating spacer 726A and the second insulating spacer 726B are formed on the fin type active region AC of the substrate 102, and the first drain region 112A and the second drain region 112B that are surrounded by the drift region 110, the first source region 132A and the second source region 132B that are respectively surrounded by the first shallow well region 130A and the second shallow well region 130B, the first body contact region 136A adjacent to the first source region 132A in the first shallow well region 130A, and the second body contact region 136B adjacent to the second source region 132B in the second shallow well region 130B, are formed in the active region AC.

However, in the present embodiment, a process of forming the third body contact region 736 between the first shallow well region 130A and the second shallow well region 130B in the drift region 110 is omitted. Accordingly, a resultant structure in which the drift region 110 is exposed through a space between the two adjacent dummy gates 208 is obtained.

Referring to FIG. 19B, by performing the processes described with reference to FIGS. 18D through 18F, the metal silicide film 125 and the contact plugs 127 are formed on each of the first drain region 112A and the second drain region 112B, the first source region 132A and the second source region 132B, the first body contact region 136A and the second body contact region 136B.

Thereafter, devices performing a desired function may be implemented by forming wirings (not shown) selectively connected to the plurality of contact plugs 127.

The processes for manufacturing the semiconductor device 500 illustrated in FIGS. 5A through 5C, the semiconductor device 700 illustrated in FIGS. 7A through 7C, and the semiconductor device 900 illustrated in FIGS. 9A through 9C are described with reference to FIGS. 17A through 19B, but the inventive concept is not limited thereto.

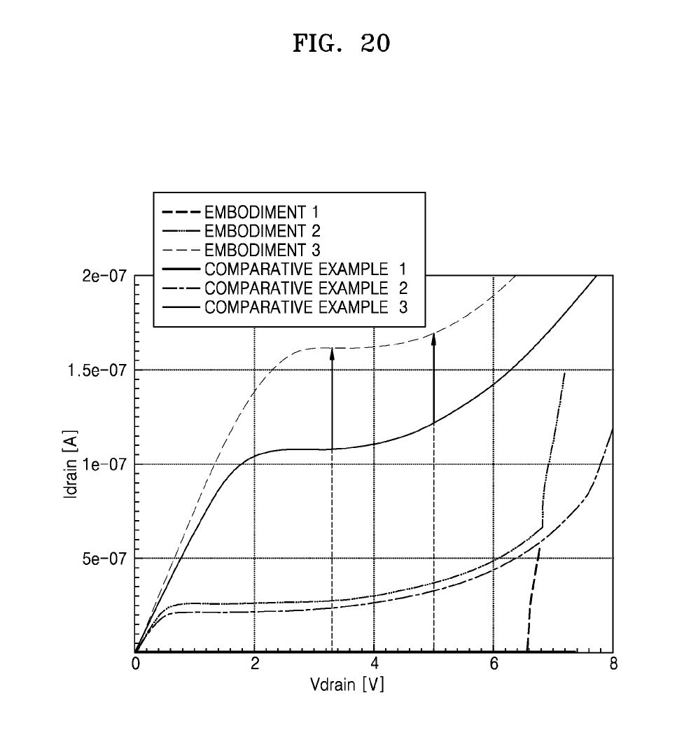

FIG. 20 is a graph illustrating a relationship between a drain current Idrain and a drain voltage Vdrain of semiconductor devices according to embodiments 1, 2, and 3 of the inventive concept, and semiconductor devices according to comparative examples 1, 2, and 3.

In more detail, embodiments 1, 2, and 3 correspond to an N-channel LDMOS transistor including the same elements as those of the semiconductor device 500 having a structure in which the first source region 132A and the first body contact region 136A, and the second source region 132B and the second body contact region 136B, are respectively surrounded by the first shallow well region 130A and the second shallow well region 130B in the drift region 110 as illustrated in FIGS. 5A through 5C, respectively. Comparison examples 1, 2, and 3 correspond to a P-channel LDMOS transistor having a structure similar to that illustrated in FIGS. 5A through 5C, except that the first source region 132A and the first body contact region 136A, and the second source region 132B and the second body contact region 136B are formed outside the drift region 110.

Referring to embodiment 1 and comparative example 1 of FIG. 20, a gate voltage Vg is input as 0.0 V, in embodiment 2 and comparative example 2, the gate voltage Vg is input as 0.9 V, in embodiment 3 and comparative example 3, the gate voltage Vg is input as 1.8 V, and the drain voltage Vdrain is measured in the range of 0 V through 8 V before each of the P and N-channel LDMOS transistors fail.

The evaluation results of FIG. 20 show that on current Ion is improved in embodiments 1 through 3 compared to comparative examples 1 through 3. In particular, in embodiment 1, when the gate voltage is input as 1.8 V, the on current Ion is improved about 49% at 3.3 V of the drain voltage Idrain.

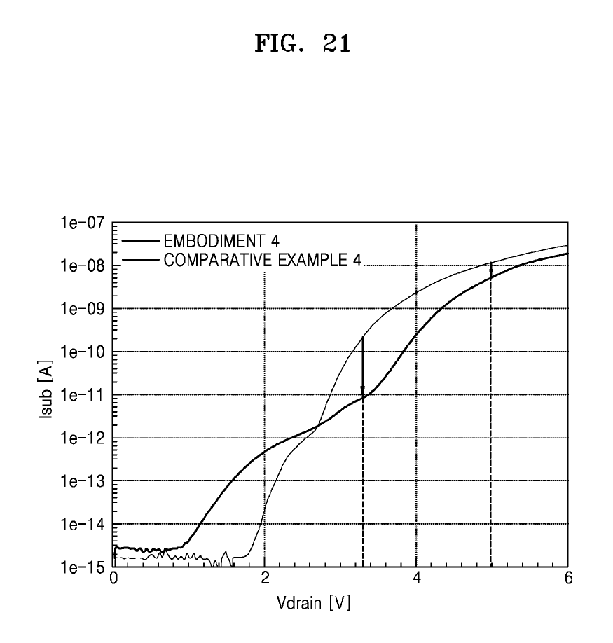

FIG. 21 is a graph illustrating a relationship between the substrate current Isub and the drain voltage Idrain of semiconductor devices according to another embodiment 4 of the inventive concept and semiconductor devices according to a comparative example 4.

In more detail, embodiment 4 of the inventive concept relates to an evaluation result regarding an N-channel LDMOS transistor having the same structure as those of embodiments 1 through 3 used for the evaluation of FIG. 20. Comparative example 4 relates to an evaluation result regarding an N-channel LDMOS transistor having the same structure as those of comparative examples 1 through 3 used for the evaluation of FIG. 20.

For evaluation of FIG. 21, in embodiment 4 and comparative example 4, the gate voltage Vg is input as 0.9 V, the substrate current Isub is measured by varying the drain voltage Idrain in the range of 0 V through 6 V.

The evaluation results of FIG. 21 show that when the drain voltage Vdrain is 3.3 V and 5.0 V, the substrate voltage Isub is reduced in embodiment 4, and thus a leakage current is reduced compared to comparative example 4.

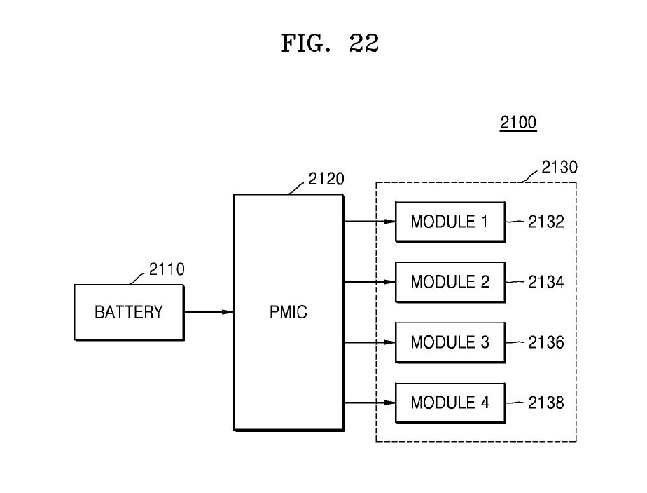

FIG. 22 is a block diagram illustrating a semiconductor system 2100 including a semiconductor device, according to an embodiment of the inventive concept.

Referring to FIG. 22, the semiconductor system 2100 includes a battery 2110, a power management IC (PMIC) 2120, and a plurality of modules 2130. The plurality of modules 2130 may include a first module 2132, a second module 2134, a third module 2136, and a fourth module 2138.

The PMIC 2120 may receive a voltage from the battery 2110, convert the voltage into a voltage level necessary for each of the plurality of modules 2130, and provide the voltage to the first through fourth modules 2132, 2134, 2136, and 2138. The PMIC 2120 may include a semiconductor device having a structure of one of the semiconductor devices 100, 200, 300, 400, 500, 600, 700, 800, 900, 1000, 1100, 1200, 1300, 1400, and 1500 according to the embodiments described with reference to FIGS. 1A through 15, or at least one structure selected from various structures modified and changed within the inventive concept therefrom.

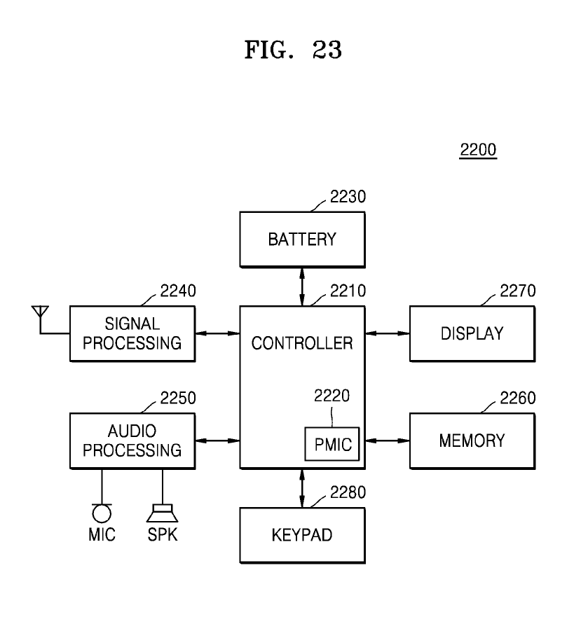

FIG. 23 is a block diagram illustrating a semiconductor system 2200 including a semiconductor device, according to another embodiment of the inventive concept.

Referring to FIG. 23, the semiconductor system 2200 may be a portable terminal. The semiconductor system 2200 includes a control unit 2210, a PMIC 2220, a battery 2230, a signal processing unit 2240, an audio processing unit 2250, a memory unit 2260, and a display unit 2270.

A keypad 2280 includes a plurality of keys for inputting numbers and/or character information and a plurality of function keys for setting various functions.

The signal processing unit 2240 may perform a wireless communication function of a portable terminal and may include an RF unit and a modem. The RF unit may include an RF transmitter that modulates and amplifies a frequency of a transmitted signal and an RF receiver that performs low pass filtering on and demodulates a received signal. The modem may include a transmitter that encodes and modulates a signal that is to be transmitted and a receiver that demodulates and decodes the signal received from the RF unit.

The audio processing unit 2250 may be configured as a codec that includes a data codec and an audio codec. The data codec may process packet data. The audio codec may process an audio signal such as voice and a multimedia file. The audio processing unit 2250 performs a function of converting and reproducing a digital audio signal received from the modem into an analog signal through the audio codec or converting an analog audio signal generated from a microphone into the digital audio signal through the audio codec and transmitting the digital audio signal to the modem. The codec may be separately provided or may be included in the control unit 2210 of the portable terminal.

The memory unit 2260 may be configured as a ROM and a RAM. The memory unit 2260 may be configured as a program memory and data memories, and may store programs for controlling an operation of the portable terminal and booting data.

The display unit 2270 may display an image signal and user data on a screen or may display data related to making a call. The display unit 2270 may be formed as a liquid crystal display (LCD) or an organic light emitting diode (OLED). When the LCD or the OLED is implemented as a touch screen, the display unit 2270 may operate as an input unit for controlling the portable terminal along with the keypad 2280.

The control unit 2210 may perform a function of controlling a general operation of the portable terminal. The control unit 2210 may include the PMIC 2220. The PMIC 2220 receives a voltage from the battery 2230 and converts the voltage into a desired voltage level. The PMIC 2220 may include a semiconductor device having a structure of one of the semiconductor devices 100, 200, 300, 400, 500, 600, 700, 800, 900, 1000, 1100, 1200, 1300, 1400, and 1500 according to the embodiments described with reference to FIGS. 1A through 15, or at least one structure selected from various structures modified and changed within the inventive concept therefrom.

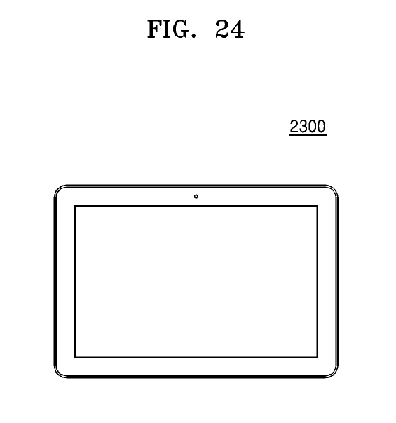

FIG. 24 is a diagram of a tablet PC 2300 including a semiconductor device, according to an embodiment of the inventive concept.

Referring to FIG. 24, the tablet PC 2300 may include a semiconductor device having a structure of one of the semiconductor devices 100, 200, 300, 400, 500, 600, 700, 800, 900, 1000, 1100, 1200, 1300, 1400, and 1500 according to the embodiments described with reference to FIGS. 1A through 15, or at least one structure selected from various structures modified and changed within the inventive concept therefrom.

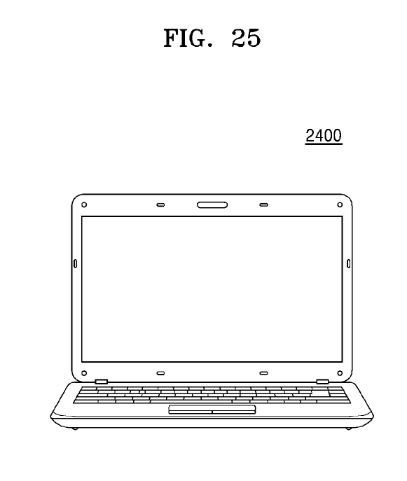

FIG. 25 is a diagram of a notebook 2400 including a semiconductor device, according to an embodiment of the inventive concept.

Referring to FIG. 25, the notebook 2400 may include a semiconductor device having a structure of one of the semiconductor devices 100, 200, 300, 400, 500, 600, 700, 800, 900, 1000, 1100, 1200, 1300, 1400, and 1500 according to the embodiments described with reference to FIGS. 1A through 15, or at least one structure selected from various structures modified and changed within the inventive concept therefrom.

While the inventive concept has been particularly shown and described with reference to exemplary embodiments thereof, it will be understood that various changes in form and details may be made therein without departing from the spirit and scope of the following claims.

1. A semiconductor device comprising:
a substrate comprising an active region of a first conductive type;
a drift region of a second conductive type in the active region;
a gate covering the active region and in the drift region;
a gate insulating film disposed between the active region and the gate;
a drain region of the second conductive type in the drift region, spaced apart from the gate, and having a higher doping concentration than the drift region;
a shallow well region of the first conductive type between the gate and the drain region and spaced apart from the drain region, and in the drift region; and
a source region of the second conductive type in the shallow well region between the gate region and the drain region and having a higher doping concentration than the shallow well region.

2. (canceled)

3. The semiconductor device of claim 1, further comprising a body contact region of the first conductive type in the shallow well region, between the source region and the drain region, and spaced apart from the drain region.

4. The semiconductor device of claim 1, wherein the substrate comprises:
a main surface; and
a fin type semiconductor region protruding from the main surface and extending in a first direction parallel to the main surface of the substrate,
wherein the active region is defined in the fin type semiconductor region.

5. (canceled)

6. The semiconductor device of claim 4, wherein the gate comprises a first vertical gate unit and a second vertical gate unit facing two side surfaces of the active region, and
the gate insulating film is between the first vertical gate unit and one of the two side surfaces of the active region, and between the second vertical gate unit and an other of the two side surfaces of the active region.

7. The semiconductor device of claim 4, wherein the gate comprises a first vertical gate unit, a second vertical gate unit, and a horizontal gate unit integrally connected to the first vertical gate unit and the second vertical gate unit,
the first vertical gate unit and the second vertical gate unit face two side surfaces of the active region, with the gate insulating film therebetween, and
the horizontal gate unit faces an upper surface of the active region, and the gate insulating film is between the horizontal gate unit and the upper surface of the active region.

8. The semiconductor device of claim 1, wherein the substrate is a bulk substrate, and wherein the gate is a planar type gate formed on the bulk substrate.

9. A semiconductor device comprising:
a substrate comprising an active region of a first conductive type;
a drift region of a second conductive type in the active region;
a gate region comprising at least one gate covering the active region and on the drift region;
at least one gate insulating film disposed between the active region and the at least one gate;
a first shallow well region and a second shallow well region of the first conductive type in the drift region and spaced apart from each other, wherein the gate region is between the first shallow well region and the second shallow well region;
a first source region of the second conductive type in the first shallow well region and having a higher doping concentration than the first shallow well region;
a second source region of the second conductive type in the second shallow well region and having a higher doping concentration than the second shallow well region; and
a first drain region and a second drain region of the second conductive type in the drift region and spaced apart from each other and the gate region, wherein the first shallow well region and the second shallow well region are between the first drain region and the second drain region, and the first drain region and the second drain region have a higher doping concentration than the drift region.

10. The semiconductor device claim 9, wherein the gate region comprises a common gate, and the semiconductor device comprises:
a first lateral diffused metal oxide semiconductor (LDMOS) transistor comprising the first source region and the first drain region in the drift region; and
a second LDMOS transistor comprising the second source region and the second drain region in the drift region,
wherein the common gate is shared by the first LDMOS transistor and the second LDMOS transistor.

11-12. (canceled)

13. The semiconductor device of claim 9, wherein the gate region comprises a first gate and a second gate spaced apart from each other, and the semiconductor device comprises:
a first LDMOS transistor comprising the first gate region, the first source region, and the first drain region in the drift region; and
a second LDMOS transistor comprising the second gate region, the second source region, and the second drain region in the drift region.

14-15. (canceled)

16. The semiconductor device of claim 13, further comprising a device isolation film in the drift region between the first gate and the second gate.

17. The semiconductor device of claim 13, further comprising:
a first body contact region of the first conductive type in the first shallow well region between the first source region and the first drain region, and spaced apart from the first drain region;
a second body contact region of the first conductive type in the second shallow well region between the second source region and the second drain region, and spaced apart from the second drain region; and
a third body contact region in the drift region between the first gate and the second gate.

18. The semiconductor device of claim 13, further comprising:
a first body contact region of the first conductive type in the first shallow well region between the first source region and the first drain region, and spaced apart from the first drain region;
a second body contact region of the first conductive type in the second shallow well region between the second source region and the second drain region, and spaced apart from the second drain region; and
an impurity region of the first conductive type in the drift region between the first gate and the second gate, wherein the inpurity region is electrically floating.

19. The semiconductor device of claim 9, wherein the substrate comprises a main surface and a fin type semiconductor region protruding from the main surface of the substrate and extending in a first direction parallel to the main surface of the substrate,
wherein the active region is defined in the fin type semiconductor region.

20-21. (canceled)

22. The semiconductor device of claim 9, wherein the substrate is a bulk substrate, and the at least one gate is a planar type gate on the bulk substrate.

23. A semiconductor device comprising:
a fin type active region of a first conductive type on a substrate and extending in a first direction;
a gate region on the substrate, extending in a direction crossing the fin type active region, and comprising at least one gate covering two side surfaces of the fin type active region;
a first source region and a second source region of a second conductive type in the fin type active region at two side surfaces of the gate region;
a first drain region of the second conductive type in the fin type active region and spaced apart from the gate region, wherein the first source region is between the first drain region and the gate region;
a second drain region of the second conductive type in the fin type active region and spaced apart from the gate region, wherein the second source region is between the second drain region and the gate region; and
a drift region of the second conductive type in the fin type active region and surrounding the gate region, the first source region, the second source region, the first drain region, and the second drain region.

24. The semiconductor device of claim 23, further comprising:
a first well of the first conductive type in the drift region and surrounding the first source region; and
a second well of the first conductive type in the drift region and surrounding the second source region.

25. (canceled)

26. The semiconductor device claim 23, wherein the gate region comprises a common gate, and the semiconductor device comprises:
a first LDMOS transistor comprising the first source region and the first drain region in the drift region; and
a second LDMOS transistor comprising the second source region and the second drain region in the drift region,
wherein the common gate is shared by the first LDMOS transistor and the second LDMOS transistor.

27. The semiconductor device of claim 23, wherein the gate region comprises a first gate and a second gate spaced apart from each other, and the semiconductor device comprises:
a first LDMOS transistor comprising the first gate region, the first source region, and the first drain region in the drift region; and
a second LDMOS transistor comprising the second gate region, the second source region, and the second drain region in the drift region.

28. The semiconductor device of claim 27, further comprising a first conductive type body contact region between the first gate and the second gate.

29. The semiconductor device of claim 27, further comprising a device isolation film between the first gate and the second gate.

30-44. (canceled)
